(19) United States
(12) Patent Application Publication
(10) Pub. No.: US 2022/0189846 A1
(43) Pub. Date: Jun. 16, 2022

(54) MATERIAL GROWTH ON WIDE-BANDGAP SEMICONDUCTOR MATERIALS

(71) Applicant: Akash Systems, Inc., San Francisco, CA (US)

(72) Inventors: Daniel FRANCIS, San Francisco, CA (US); Felix EJECKAM, San Francisco, CA (US); Tyrone D. MITCHELL, JR., San Francisco, CA (US); Paul SAUNIER, San Francisco, CA (US)

(21) Appl. No.: 17/556,312

(22) Filed: Dec. 20, 2021

Related U.S. Application Data
(63) Continuation of application No. PCT/US2020/039161, filed on Jun. 23, 2020.
(60) Provisional application No. 62/865,919, filed on Jun. 24, 2019.

(51) Int. Cl. H01L 23/373; H01L 23/66; H01L 21/02

(52) U.S. Cl. CPC H01L 23/3732; H01L 23/66; H01L 21/02389; H01L 21/02527; H01L 21/02609; H01L 21/0262; H01L 2223/6677; H01L 2223/6683; H01L 21/02658

(57) ABSTRACT

Aspects of diamond growth on semiconductors are described. Some aspects include direct growth of synthetic diamond on wide-bandgap semiconductors without the use of nucleating layers or protective layers. Some aspects include generating synthetic diamond over a gallium nitride surface of a layered structure in accordance with a set of growth parameters that are generated based at least in part on an interface property of an interface generated between the gallium nitride surface and the synthetic diamond. In some aspects, the interface is a single interface between the synthetic diamond and the gallium nitride surface. In some aspects, the synthetic diamond is in contact with the gallium nitride surface. Some aspects include synthetic diamond growth on wide-bandgap semiconductor structures to achieve thermal extraction without introducing electrically conductive regions in the semiconductor structure. Such aspects may include generating less than optimal quality synthetic diamond.

### CROSS-REFERENCE

This application is a continuation of International Application No. PCT/US2020/039161, filed Jun. 23, 2020, which claims the benefit of U.S. Provisional Patent Application Ser. No. 62/865,919 filed Jun. 24, 2019, both of which are hereby incorporated by reference in their entireties.

### BACKGROUND

As development of wide-bandgap semiconductor devices continues to evolve, the demand for efficiency increases. Semiconductor devices such as power amplifiers can exhibit improved thermal efficiencies and operating temperatures with improved performance and reliability through the use of wide-bandgap semiconductors. The integration of diamond heat-sinks or diamond substrates with wide-bandgap semiconductors has helped drive improvements in thermal efficiency. However, challenges arise with such integration given the incompatibilities of the high process temperatures of diamond with such semiconductor materials.

### SUMMARY

To improve the thermal efficiencies of wide-bandgap semiconductor devices, particularly for high-power and high-frequency applications, it may be desirable to grow diamond directly on such semiconductor materials without the use of a nucleating layer, which can limit thermal performance. However, exposing wide-bandgap semiconductor materials to the high process temperatures of diamond can damage a semiconductor surface. The present disclosure provides devices, systems and methods comprising layered structures and substrates. Some aspects of the present disclosure provide devices, systems and methods that comprise diamond layers generated on wide-bandgap semiconductor materials. Some aspects relate to gallium nitride (GaN) on diamond (GaN-D).

In an aspect, a semiconductor apparatus is provided. The semiconductor apparatus may comprise: a layered structure including a wide-bandgap semiconductor material; and at least one layer of synthetic diamond disposed over and in contact with at least a portion of the layered structure at an interface, wherein a thermal conductivity of the at least one layer of synthetic diamond is from about 50 W/mK to about 500 W/mK.

In some embodiments, the at least one layer of synthetic diamond has a thickness from about 20 nanometers (nm) to about 2,000 nm. In some embodiments, the at least one layer of synthetic diamond has a thickness less than 2,000 nm, less than 1,000 nm, less than 500 nm, or less than 100 nm. In some embodiments, the wide-bandgap semiconductor material comprises a material selected from the group consisting of GaN, AlN, InGaN, InAlN, AlGaN, InGaAlN, Ga2O3, ScAlN, and derivatives and combinations thereof. In some embodiments, the interface is a single interface between the at least one layer of synthetic diamond and at least a portion of the wide-bandgap semiconductor material. In some embodiments, the single interface includes at least a portion of the at least one layer of synthetic diamond in contact with the at least a portion of the wide-bandgap semiconductor material. In some embodiments, the semiconductor apparatus does not include a nucleation layer or an intermediating layer over the at least the portion of the layered structure.

In some embodiments, the interface comprises a thermal boundary having a resistance less than about 50 m²K/GW, as measured by time-domain thermal reflectance. In some embodiments, the interface comprises a thermal boundary having a resistance less than about 15 m²K/GW, as measured by time-domain thermal reflectance. In some embodiments, the interface comprises a charge density less than or equal to about 10¹⁷ carriers/cm² at 23° C. as measured by capacitance-voltage testing. In some embodiments, the interface comprises a charge density less than or equal to about 10¹⁶ carriers/cm² at 23° C. as measured by capacitance-voltage testing. In some embodiments, the semiconductor apparatus further comprises at least one additional layer of synthetic diamond over the at least one layer of synthetic diamond. In some embodiments, a thermal conductivity of the at least one additional layer of synthetic diamond is greater than about 1,000 W/mK. In some embodiments, the at least one additional layer of synthetic diamond has a thickness of about 500 micrometers or less. In some embodiments, the interface has a roughness of less than about 5 atomic layers, less than about 3 atomic layers, less than about 2 atomic layers, or less than about 1 atomic layer, when viewed by scanning electron or tunneling electron microscopy.

In another aspect, a semiconductor-containing structure is provided. The semiconductor-containing structure may comprise a structure of a semiconductor material in contact with at least one layer of synthetic diamond at a single interface, wherein a thermal conductivity of the at least one layer of synthetic diamond is within a range from about 50 W/mK to about 500 W/mK. In some embodiments, the structure is a layered structure. In some embodiments, the semiconductor material is a wide-bandgap semiconductor material comprising a material selected from the group consisting of GaN, AlN, InGaN, InAlN, AlGaN, InGaAlN, Ga2O3, ScAlN, and derivatives and combinations thereof.

In some embodiments, the at least one layer of synthetic diamond has a thickness within a range from about 20 nanometers (nm) to about 2,000 nm. In some embodiments, the at least one layer comprises a thickness less than 2,000 nm, less than 1,000 nm, less than 500 nm, or less than 100 nm. In some embodiments, the structure does not include a nucleation layer or an intermediating layer over the at least the portion of the layered structure. In some embodiments, the interface comprises a thermal boundary having a resistance less than about 50 m²K/GW, as measured by time-domain thermal reflectance. In some embodiments, the interface comprises a thermal boundary having a resistance less than about 15 m²K/GW, as measured by time-domain thermal reflectance. In some embodiments, the interface comprises a charge density less than or equal to about 10¹⁷ carriers/cm² at 23° C. as measured by capacitance-voltage testing. In some embodiments, the interface comprises a charge density less than or equal to about 10¹⁶ carriers/cm² at 23° C. as measured by capacitance-voltage testing. In some embodiments, the semiconductor-containing structure comprises at least one additional layer of synthetic diamond over the at least one layer of synthetic diamond. In some embodiments, a thermal conductivity of the at least one additional layer of synthetic diamond is greater than about 1,000 W/mK. In some embodiments, the at least one additional layer of synthetic diamond has a thickness of about 500 micrometers or less. In some embodiments, the interface has a roughness of less than about 5 atomic layers, less than about 3 atomic layers, less than about 2 atomic layers, or less than about 1 atomic layer, when viewed by scanning electron or tunneling electron microscopy.

In another aspect, a method of manufacturing a compound semiconductor is provided. The method may comprise: (a) providing a layered structure within a vapor deposition chamber, the layered structure including a wide-bandgap semiconductor material; and (b) generating at least one layer of synthetic diamond over at least a portion of the layered structure in accordance with a set of growth parameters, which set of growth parameters is generated based at least in part on at least one interface property of an interface to be generated between the layered structure and at least one layer of synthetic diamond to be generated, wherein the set of growth parameters includes one or more parameters selected from the group consisting of a temperature of the layered structure, a flow rate of a carbon-containing gas, and a flow rate of a carrier gas.

In some embodiments, the method comprises: (i) heating the layered structure to the temperature; and (ii) introducing a flow of the carbon-containing gas and a flow of the carrier gas to deposit the at least one layer of synthetic diamond over the at least a portion of the layered structure.

In some embodiments, the interface is a single interface between the at least one layer of synthetic diamond and at least a portion of the wide-bandgap semiconductor material. In some embodiments, the single interface includes at least a portion of the at least one layer of synthetic diamond in contact with the at least a portion of the wide-bandgap semiconductor material. In some embodiments, the carbon-containing gas includes methane or carbon dioxide, and wherein the carrier gas includes argon or hydrogen. In some embodiments, the at least one interface property is a charge density no greater than 1016 carriers/cm2 at 23° C. as measured by capacitance-voltage testing. In some embodiments, the temperature is from about 450° C. to about 600° C. In some embodiments, the flow rate of the carrier gas is about 2,000 standard cubic centimeters per minute (SCCM) or less. In some embodiments, the flow rate of the carbon-containing gas is within a range from about 0.5% of a flow rate of the carrier gas to about 3.5% of the flow rate of the carrier gas. In some embodiments, the method comprises introducing a flow of a nitrogen gas into the vapor deposition chamber. In some embodiments, the at least one layer of synthetic diamond has a thermal conductivity from about 50 W/mK to about 500 W/mK. In some embodiments, the interface property is a thermal boundary having a resistance less than about 15 m²K/GW, as measured by time-domain thermal reflectance. In some embodiments, the at least one layer of synthetic diamond has a thickness within a range from about 20 nanometers (nm) to about 2,000 nm. In some embodiments, the wide-bandgap semiconductor material comprises a material selected from the group consisting of GaN, AlN, InGaN, InAlN, AlGaN, InGaAlN, Ga2O3, ScAlN, and derivatives and combinations thereof. In some embodiments, the method comprises: generating at least one additional layer of synthetic diamond over the at least one layer of synthetic diamond in accordance with an additional set of growth parameters, wherein the additional set of growth parameters is based at least in part on a thermal conductivity of the at least one layer of synthetic diamond, wherein the additional set of growth parameters includes one or more parameters selected from the group consisting of a temperature of the layered structure, a flow rate of a carbon-containing gas, and a flow rate of a carrier gas.

In some embodiments, the at least one additional layer of synthetic diamond is generated at least in part by: heating the layered structure including the at least one layer of synthetic diamond to a second temperature; and introducing a second flow of the carbon-containing gas and a second flow of the carrier gas. In some embodiments, the second temperature is greater than about 600° C. In some embodiments, a thermal conductivity of the at least one additional layer of synthetic diamond is greater than about 1,000 W/mK. In some embodiments, the at least one additional layer of synthetic diamond has a thickness of about 500 micrometers or less. In some embodiments, the method comprises, prior to (b), generating the set of growth parameters. In some embodiments, the at least one layer of synthetic diamond is generated without formation of a nucleation layer or an intermediating layer over the at least the portion of the layered structure. In some embodiments, the at least one layer of synthetic diamond is generated without selective area nucleation. In some embodiments, the one or more parameters comprise a temperature of the layered structure, a flow rate of a carbon-containing gas, and a flow rate of a carrier gas.

In another aspect, a method for forming a semiconductor-containing structure is provided. The method may comprise forming at least one layer of synthetic diamond in contact with a structure of a wide-bandgap semiconductor material at a single interface, wherein a thermal conductivity of the at least one layer of synthetic diamond is from about 50 W/mK to about 500 W/mK. In some embodiments, the structure is a layered structure.

In some embodiments, the wide-bandgap semiconductor material comprises a material selected from the group consisting of GaN, AlN, InGaN, InAlN, AlGaN, InGaAlN, Ga2O3, ScAlN, and derivatives and combinations thereof. In some embodiments, the at least one layer of synthetic diamond has a thickness within a range from about 20 nanometers (nm) to about 2,000 nm. In some embodiments, the at least one layer comprises a thickness less than 2,000 nm, less than 1,000 nm, less than 500 nm, or less than 100 nm. In some embodiments, the semiconductor apparatus does not include a nucleation layer or an intermediating layer over the at least the portion of the layered structure. In some embodiments, the interface comprises a thermal boundary having a resistance less than about 50 m²K/GW, as measured by time-domain thermal reflectance. In some embodiments, the interface comprises a thermal boundary having a resistance less than about 15 m²K/GW, as measured by time-domain thermal reflectance. In some embodiments, the interface comprises a charge density less than or equal to about 10¹⁷ carriers/cm² at 23° C. as measured by capacitance-voltage testing. In some embodiments, the interface comprises a charge density less than or equal to about 10¹⁶ carriers/cm² at 23° C. as measured by capacitance-voltage testing. In some embodiments, the semiconductor-containing structure further comprises at least one additional layer of synthetic diamond over the at least one layer of synthetic diamond. In some embodiments, a thermal conductivity of the at least one additional layer of synthetic diamond is greater than about 1,000 W/mK. In some embodiments, the at least one additional layer of synthetic diamond has a thickness of about 500 micrometers or less. In some embodiments, the method further comprises forming a chip comprising the semi-conductor-containing structure. In some embodiments, the chip comprises a transistor. In some embodiments, the method further comprises forming a device for transmitting or receiving electromagnetic signals comprising the chip. In some embodiments, the interface has a roughness of less than about 5 atomic layers, less than about 3 atomic layers, less than about 2 atomic layers, or less than about 1 atomic layer, when viewed by scanning electron or tunneling electron microscopy.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure.

Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference. To the extent publications and patents or patent applications incorporated by reference contradict the disclosure contained in the specification, the specification is intended to supersede and/or take precedence over any such contradictory material.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which various principles of the invention are utilized, and the accompanying drawings or figures (also “FIG.” and “FIGS.” herein), of which:

FIG. 1 illustrates a cross-sectional view of an example substrate, in accordance with some embodiments disclosed herein.

FIG. 2 illustrates a cross-sectional view of an example substrate, in accordance with some embodiments disclosed herein.

FIG. 3 illustrates a cross-sectional view of an example substrate, in accordance with some embodiments disclosed herein.

FIG. 4 illustrates an example of a material interface, in accordance with some embodiments disclosed herein.

FIG. 5 illustrates generally a flowchart of an example method of manufacturing a substrate, in accordance with some embodiments disclosed herein.

FIG. 6 illustrates generally a flowchart of an example method of manufacturing a substrate, in accordance with some embodiments disclosed herein

FIG. 7 illustrates generally a flowchart of an example method of manufacturing a substrate, in accordance with some embodiments disclosed herein.

FIG. 8 illustrates generally a flowchart of an example method of manufacturing a substrate, in accordance with some embodiments disclosed herein.

FIG. 9 illustrates a cross-sectional view of an example substrate, in accordance with some embodiments disclosed herein.

FIG. 10A illustrates a cross-sectional view of an example substrate, in accordance with some embodiments disclosed herein.

FIG. 10B illustrates a cross-sectional view of an example substrate, in accordance with some embodiments disclosed herein.

FIG. 11 illustrates a cross-sectional view of an example substrate, in accordance with some embodiments disclosed herein.

FIG. 12 illustrates a block diagram of an example system including one or more devices comprising a compound semiconductor substrate, in accordance with some embodiments disclosed herein.

FIG. 13 illustrates a block diagram of an example wireless device, in accordance with some embodiments disclosed herein.

FIG. 14 illustrates a block diagram of an example control-communications block of a wireless device, in accordance with some embodiments disclosed herein.

FIG. 15 illustrates a block diagram representing various examples of wireless communication networks, in accordance with some embodiments disclosed herein.

### DETAILED DESCRIPTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

It shall be understood that different aspects of the invention can be appreciated or modified individually, collectively, or in combination with each other. Where values are described as ranges, it will be understood that such disclosure includes the disclosure of all possible sub-ranges within such ranges, as well as specific numerical values that fall within such ranges irrespective of whether a specific numerical value or specific sub-range is expressly stated.

The present disclosure provides devices, systems, and methods comprising layered structures and substrates having improved thermal efficiencies. Such devices may include one or more transistors. Devices may include integrated circuits, power amplifiers and radio transmitters, for use in high-frequency applications, for example, millimeter wave (mmWave) applications. Such devices may provide improved performance at X-band frequency ranges (e.g., 8-12 GHz), K-band frequency ranges (e.g., 17-20 GHz, 37-40 GHz), V-band frequency ranges (e.g., 40-75 GHz), W-band frequency ranges (e.g., 75-110 GHz), G-band frequency ranges (e.g., 110-300 GHz), E-band frequency ranges (e.g., 60-90 GHz), or other suitable frequency ranges. Aspects of the present disclosure may be applicable to other types of electronic and optoelectronic devices, for example, microwave diodes and lasers.

Devices comprising nucleating layers may have less than optimal thermal efficiency as such nucleating layers may introduce barriers to thermal energy transfer. Compound semiconductor substrates comprising diamond grown directly on semiconductor layers can address such thermal efficiency challenges.

Aspects of the present disclosure provide methods of generating (e.g., growing, depositing) diamond directly on semiconductor-containing materials. Some aspects provide methods of manufacturing semiconductor substrates. Some aspects provide devices comprising such semiconductor substrates. Disclosed are methods of growing diamond directly on semiconductor-containing materials to achieve improved thermal efficiency while avoiding damage to such materials. Aspects may also include growing diamond directly on semiconductor-containing materials without the use of SAD and photoresist materials (or other methods and materials) for seeding diamond particles.

Aspects of the present disclosure provide methods of generating diamond directly on semiconductor-containing materials to achieve thermal extraction without introducing electrically conductive regions on or within the semiconductor material. Some examples may include generating less than optimal quality diamond. Some examples may include generating low quality diamond. Some examples may include generating less than optimal quality diamond at an early or initial stage of an overall diamond growth process.

Unless otherwise defined, all technical terms used herein have the same meaning as commonly understood by one of ordinary skill in the art to which this invention belongs. As used in this specification and the appended claims, the singular forms “a,” “an,” and “the” include plural references unless the context clearly dictates otherwise. Any reference to “or” herein is intended to encompass “and/or” unless otherwise stated.

The term “wide-bandgap” and “wide-gap” (or variations thereof), as used herein in the context of semiconductor technology, generally refer to electronic and/or optoelectronic devices and manufacturing technologies based on wide-bandgap semiconductors. A wide-bandgap semiconductor may have a bandgap in a range of 2-4 electronvolt (eV), for example. A wide-bandgap semiconductor may have a bandgap in a range greater than about 3.4 eV. A wide-bandgap semiconductor can comprise, for example, in relation to the Periodic Table of the Elements: (a) semiconductors comprising a bond between nitrogen (N) and at least one Group III element, (b) semiconductors comprising a bond between carbon (C) and at least one Group IV element, or (c) semiconductors comprising a bond between oxygen (O) and at least one Group II element. A wide-bandgap semiconductor, for example, may comprise one or more materials including gallium, aluminum, indium, boron, scandium, nitrogen, and derivatives thereof. In some examples, a wide-bandgap semiconductor may include gallium nitride (GaN), aluminum nitride (AlN), indium gallium nitride (InGaN), indium aluminum nitride (InAlN), aluminum gallium nitride (AlGaN), indium gallium aluminum nitride (InGaAlN), gallium oxide (Ga2O3) or derivatives thereof. Such materials may improve performance efficiency in high-power microwave devices, which can exhibit electron mobilities, breakdown voltages, and thermal conductivities that exceed other semiconductor materials, such as gallium arsenide (GaAs), indium phosphide (InP), or silicon.

The term “thermal budget,” as used herein, generally refers to an assessment of temperature dissipation from one or more components to an environment. For example, a thermal budget may define an amount of thermal energy transferred from a heat source (e.g., active layers of a device) to a surrounding environment. The active layers of a semiconductor device may be several micrometers thick and may be disposed adjacent to mechanical carriers or substrates.

The term “substrate,” as used herein, generally refers to any substance upon which a layered structure is deposited. The substrate may comprise a foundation for the fabrication of electronic devices, such as transistors, diodes, and integrated circuits. The substrate may comprise a solid material such as a semiconductor or an insulator. The substrate may comprise a wide-bandgap semiconductor. The substrate may comprise a carbon-containing material, such as diamond, synthetic diamond, diamond-like carbon, graphene, diamond nanoparticles or Nano diamond. The substrate material may be single crystalline, poly crystalline or amorphous. Substrate materials may comprise, for example, carbon, aluminum, gallium, silicon, germanium, arsenic, thallium, cadmium, tellurium, selenium, or alloy or allotrope thereof, or an oxide or nitride thereof. The substrate may include one or more chemical dopants, such as nitrogen, phosphorous, boron or indium.

Substrate materials may comprise one or more of, for example, diamond, synthetic diamond, silicon (Si), silicon dioxide (SiO2), silicon carbide (SiC), aluminum oxide (Al2O—3), sapphire, aluminum nitride (AlN), scandium aluminum nitride (ScAlN), germanium, gallium arsenide, gallium nitride(GaN), or indium phosphide (InP), indium nitride (InN), aluminum gallium nitride (AlGaN), indium gallium nitride (InGaN), indium aluminum nitride (InAlN), zinc oxide (ZnO), for example. The substrate may include a material having a thermal conductivity equal to or greater than about 1,000 W/mK in at least a single dimension (e.g., vertical dimension, horizontal dimension).

The term “single-crystal,” as used herein, generally refer to a material having one crystal or having a translational symmetry. The term “polycrystalline” generally refers to a material having more than one crystal domain or orientation. A polycrystalline material may exhibit more than one crystal structure under low energy electron diffraction (LEED) microscopy. The term “amorphous” generally refers to a material having no real or apparent crystalline form. An amorphous material may not exhibit any long-range crystal structure under LEED.

Active layers of a semiconductor device may be epitaxially grown on a substrate. In some cases, the substrate may be of the same family of materials as the active layers of the electronic device. Electronic materials for device fabrication may be realized by attaching the active layers to substrates comprising materials having crystalline structures and material combinations different from the active layer. Examples of ways to attach semiconductors to substrates having different crystal structures can include direct-bonding or direct growth using transition layer(s) to bridge different lattice structures. Alternatives to bonding and die-attachment may include the use of selective area deposition (SAD).

The substrate may have various functions, for example, (i) mechanical support; (ii) electrical conductivity that can be used to connect the active layers to the bottom of the chip; (iii) electrical isolation with low dielectric losses that can be used in high-frequency devices and surface waveguides where electric fields penetrate into the substrate; and (iv) high thermal conductivity with or without associated electrical conductivity.

The term “layered structure,” as used herein, generally refers to structures created from layered materials of varying properties. A layered structure may comprise layers of one or more materials that may have the same or varying semiconductor properties. Individual layers may be single crystalline, polycrystalline, or amorphous. Electronic and optoelectronic devices manufactured out of layers of different semiconductor properties may be made by different growth techniques. In some cases, these growth techniques may allow for controlled growth of individual layers. In some cases, the layers may be referred to as “epitaxial layers” or “epilayers.” Each layer may be of a thickness varying from sub-nanometer to tens of microns. Non-limiting examples of manufacturing techniques include molecular beam epitaxy (MBE), vapor deposition (e.g., chemical vapor deposition (CVD), physical vapor deposition), atomic layer deposition (ALD), organo-metallic vapor-phase epitaxy, and liquid phase epitaxy.

Epitaxial layers may comprise, for example, boron, aluminum, gallium, indium, thallium, carbon, silicon, germanium, tin, lead, nitrogen, phosphorous, arsenic, antimony, bismuth, oxygen, sulfur, selenium, tellurium, beryllium, magnesium, calcium, zinc, cadmium, scandium, and alloys and allotropes thereof or an oxide or nitride thereof. Epitaxial layers may comprise wide-bandgap semiconductor materials. Epitaxial layers may comprise a material comprising: (i) a bond between at least one Group III element and at least one Group V element; (ii) a bond between nitrogen and at least one Group III element; (iii) a bond between carbon and at least one group IV element; or (iv) a bond between oxygen and at least one group II element.

Epitaxial layers may comprise, for example, gallium nitride (GaN), aluminum nitride (AlN), indium nitride (InN), aluminum gallium nitride (AlGaN), indium gallium nitride (InGaN), indium aluminum nitride (InAlN), zinc oxide (ZnO), silicon carbide (SiC), and diamond. Any such materials may be single-crystalline, polycrystalline, or amorphous.

The term “chip,” as used herein generally refers to an active electronic or optoelectronic device, which may be disposed on a substrate. A chip may comprise one or more active layers disposed a substrate. The chip may comprise a layered structure. The chip may comprise one or more transistors (e.g., field-effect transistor, bipolar transistor). A transistor may be a high-electron-mobility transistor. The chip may comprise an integrated circuit, such as a monolithic microwave integrated circuit (MMIC). The chip may perform functions such as mixing, power amplification, low noise amplification, and switching.

The term “transistor,” as used herein, generally refers to an electrical device which can act as a switch and/or an amplifier. A transistor may be a part of a digital circuit. A digital circuit may comprise a plurality of transistors. A transistor may comprise one or more contacts, a layered structure, and a substrate. A transistor may be a part of a computing device. A transistor may be a portion of a logic circuit or a logic gate. A transistor may be a semiconductor device. The term “field-effect transistor” (FET) as used herein, generally refers to a transistor which uses an electric field to control the operation of a device having the transistor. An electric field may be used to control the flow of current between two contacts or terminals in the device such as a source contact and a drain contact.

The term “high-electron-mobility transistor” (HEMT), as used herein, generally refers to a field-effect transistor comprising a heterojuction. A high-electron-mobility transistor may be alternatively referred to as a heterostructure field effect transistor. The term “heterojuction,” as used herein, may refer to the interface between any two solid-state materials of differing material properties. In some examples, these may include any two semiconductors, any two crystalline forms (e.g., amorphous, polycrystalline) of the same semiconductor, any two semiconductors comprising the same element but with varying amounts of those elements, any two semiconductors with varying dopant level, etc. The two materials may have unequal band gaps. The two materials may have a band offset. The two materials forming the heterojuction may be referred to as a “heterostructure.” In some examples, an interface between a buffer layer and a barrier layer may form a heterojunction.

The term “Schottky contact,” as used herein, generally refers to a metal-semiconductor interface with a non-zero contact resistance, measured relative to the resistance of the semiconductor. The contact may comprise an energetic barrier between states of the semiconductor and states of the metal which barrier may be non-zero. The contact may be a rectifying contact, e.g., a Schottky barrier. In some examples, devices may include one or more dielectric or insulating material layers, for example, under a gate contact. Such devices may comprise Metal-Insulator-Semiconductor Field Effect Transistors (“MISFET”s).

The term “interface,” as used herein, generally refers to a surface forming a common boundary between two different materials, for example, materials having differing crystalline structures, differing material combinations, differing material properties. The term “interface” can refer to a location where two different materials come into contact with one another. The term “interface” can also refer to the atoms of a first material combining with the atoms of a second material at a location or at a boundary, for example, without the presence of atoms of a third material. An interface may be a surface forming a common boundary between semiconductor and diamond. An interface can be a location where diamond atoms contact atoms of a wide-bandgap semiconductor. A compound substrate of the present disclosure may include a single interface. In some examples, such compound substrate may not include more than one interface.

The term “intermediate layer,” as used herein, generally refers to a material layer disposed between two material layers, for example, between two layers of materials having similar or varying properties. Intermediate layers may comprise single crystalline, polycrystalline or amorphous materials. Intermediate layers may comprise wide-bandgap semiconductors, as described herein. Intermediate layers may comprise carbon-containing materials as described herein. Individual layers surrounding an intermediate layer may comprise materials having different lattice-constants or different lattice structures. Individual layers surrounding an intermediate layer may comprise materials having different thermal conductivities and/or different sheet resistivities. An intermediate layer may comprise an interface or interface layer between two material layers. An intermediate layer may have a thickness from about sub-nanometer to tens of microns.

An intermediate layer may comprise a transition layer between two material layers or two substrates. In some examples, a transition layer may bridge a first lattice structure (e.g., first lattice constant) of a first material layer to a second lattice structure (e.g., second lattice constant) of a second material layer, for example, within a layered semiconductor structure. One or more transition layers may be used to accommodate for a change in the lattice constants and help absorb dislocations between two material layers or substrates.

An intermediate layer may comprise a nucleation layer. The term “nucleation layer” or “nucleating layer,” as used herein, generally refers to a material layer that assists in starting the growth or formation of another layer of material or stoichiometry. Nucleating layer materials can include semiconductors, for example, wide-bandgap semiconductors. Nucleating materials can include silicon, silicon nitride (SiN), silicon carbide (SiC) or other materials that may aid in the nucleation of synthetic diamond. Nucleating materials can include, for example, InGaN, InAlN, AlN, ScAlN or derivatives thereof. Nucleating layer materials can assist in preventing etching or damage to an underlying semiconductor material or substrate. Nucleating materials can be amorphous or polycrystalline. The presence of a nucleating layer may create multiple interfaces between a layered semiconductor structure and a substrate. Multiple interfaces can include, for example, (i) a first interface between a diamond substrate and a nucleating layer and (ii) a second interface between the nucleating layer and a layered semiconductor structure.

Nucleating layer(s) may be disposed between two material layers or substrates, such as two material layers having similar or varying properties. A nucleating layer may have similar properties to a material to which the nucleating layer assists in the growth of. Nucleating layers may be used in nucleating diamond on semiconductor-containing structures. Nucleating layers may be protective layers that protect such structures from damage. Such structures may include one or more nucleating layers disposed between a semiconductor-containing material and diamond. A nucleating layer may be an individual layer that is independent from a semiconductor-containing structure and may be disposed on a surface of such structure. In some cases, a nucleating layer may be nucleation material that is added to a final stage of growth of such structure (e.g., final stage of epitaxial growth), in which case the nucleation material may not be an independent layer but may be integrated into the structure near a surface (e.g., top surface). A diamond growth process can include a nucleation phase in which a nucleating layer and a set of diamond-growth conditions can enhance diamond nucleation on a host substrate. Diamond-growth conditions can include conditions within a vacuum chamber, for example, in the case of vapor deposition (e.g., CVD).

Heat removal systems for devices such as power amplifiers may be large in comparison with a heat source and may limit performance. Diamond heat-sinks, heat-spreaders, and other diamond plates may be useful in spreading heat below a semiconductor device for thermal management. A diamond heat-sink may be a thermal component to which a device can be attached, wherein the diamond heat-sink assists in spreading heat generated by the device. In some cases, diamond substrates may differ from diamond heat-sinks, heat-spreaders or plates. For example, a diamond substrate may comprise a substrate on which active electronic device layers are disposed to form a device (e.g., chip).

Substrate seeding for synthetic diamond growth may be achieved through ultrasonic seeding, a process that can include placing a substrate in an ultrasonic seeding solution or bath (e.g., containing diamond particles) and agitating the bath until the diamond particles adhere to the substrate. Manufacturing compound semiconductor substrates that include synthetic diamond presents certain challenges. For example, diamond deposition is a high-temperature process often requiring temperatures greater than about 600° C. (e.g., about 800° C.) and the use of highly reactive gases such as atomic hydrogen. Such temperatures and reactive gases (e.g., H2) may be incompatible with many semiconductors and may damage or cause defects to a semiconductor material, resulting in performance degradation of semiconductor structures and devices, among other drawbacks. Additionally, differing lattice constants between diamond and semiconductors may present challenges to integrating diamond with semiconductor devices. Bonding or die attachment methods have been common methods of integrating diamond heat sinks with semiconductor devices and circuits.

Damage or defects can include material decomposition and etching (e.g., etching by H+ formed from H2 during the diamond synthesis process). For example, hydrogen can etch a semiconductor surface, such as a GaN surface, during diamond growth causing a decrease in nitrogen and a build-up of metallic Ga on the GaN surface. Defects or damage may be measured and quantified. For example, growing diamond directly on a semiconductor material may result in a measurable interface property or surface property. A type of measurable interface property or surface property may vary based on a location on or within a compound semiconductor substrate. In some examples, the presence of metallic Ga on a GaN surface may indicate damage from hydrogen etching during diamond growth.

Such interface property or surface property can include, for example, charge density (carriers/cm²) (e.g., charge carrier density, carrier concentration, surface charge density, volume charge density, length charge density), thermal boundary resistance (m²K/_{GW}) (e.g., of a thermal boundary), thermal conductivity (W/mK), electrical conductivity (S/m), electrical resistivity (C·m), or defect density (defects/unit area). Surface charge density (σ) may be defined as the quantity of charge per unit area, at any point on a surface charge distribution on a two-dimensional surface, typically measured in coulombs per square meter (C·m⁻²). Volume charge density (ρ) may be defined as the quantity of charge per unit volume, at any point in a volume, typically measured in coulombs per cubic meter (C·m⁻³). Thermal boundary resistance (e.g., interfacial thermal resistance) may be defined as a measure of resistance to thermal energy flow at a boundary or interface (e.g., between two materials), typically caused by differences in material properties of two interfaced materials. Thermal boundary resistance can occur through energy scattering by charge carriers at a material interface. Thermal conductivity, or the measurement of the ability of a material to conduct heat, may be measured and quantified as an average value.

An interface property may be measured, for example, by capacitance-voltage (C-V) testing, four-point probe conductivity measurement, sheet resistance measurement tools, non-contact sheet resistance measurements, Eddy current measurement, laser flash, Fourier Transform Infra-Red (FTIR) analysis, Time Domain Thermal Reflectance (TDTR). An interface property may be measured at a temperature of about 23° C. An interface property may be measured by scanning electron microscopy (SEM) or by transmission electron microscopy (TEM).

Some alternatives to bonding and die-attachment may also address the concern of damage to a semiconductor material during diamond growth. Some alternatives may include selective area deposition (SAD) and the use of nucleating layers or nucleating materials for nucleating diamond on semiconductor materials. Some alternatives may include the use of selective area nucleation.

SAD can include using photoresist (or other materials) as sacrificial layers to seed and grow diamond over a semiconductor structure. SAD may also include applying nucleation layers between photoresist coatings to define areas for diamond growth on a substrate. In some cases, during ultrasonic seeding, diamond particles may adhere to the photoresist (or a nucleating material) instead of a surface of a semiconductor structure and diamond may be grown over the semiconductor structure from the seeded diamond particles in the photoresist or other material.

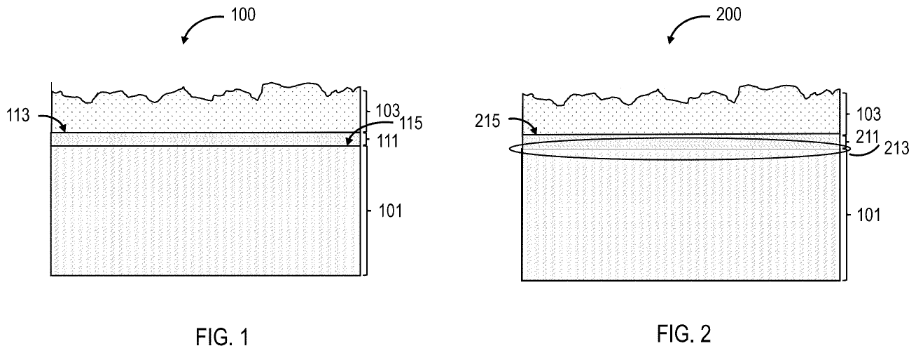

FIG. 1 illustrates a cross-sectional view of an example substrate 100, in accordance with some embodiments disclosed herein. In some examples, the substrate 100 is a compound semiconductor-containing substrate. Substrate 100 may include a layered semiconductor structure 101, a layer of carbon-containing material, such as diamond 103, an intermediate layer 111 (e.g., nucleating layer) disposed between the structure 101 and the diamond layer 103. The structure 101 may include a wide-bandgap semiconductor material. The layered structure 101 may include GaN. In some examples, the nucleation layer 111 may not be a separate layer disposed adjacent to the structure 101, for example, the structure 101 can include nucleation material (e.g., 211) grown within the structure 101, as further described herein. In some examples, structure 101 may be formed on a separate growth substrate (not shown), which may include silicon. The structure 101 may include transition layers (not shown) formed proximal to growth substrate. In some examples, the structure 101 may be epitaxially grown on a first substrate, flipped, and attached to a second substrate or carrier wafer (not shown). The first substrate may be removed from the structure 101. One or more layers of the structure 101 may also be removed (e.g., by etching or mechanical polishing). A surface of the structure 101 may be exposed for subsequent diamond growth.

The nucleation layer 111 may be used for nucleating the diamond 103 on the structure 101. The diamond 103 may be nucleated and grown on a surface 113 of the nucleating layer 111 or on a surface of a nucleating material (e.g., 211). The thickness of the nucleating layer 111 that is sufficient for diamond nucleation can depend on the material used for nucleation. The nucleation layer 111 may be formed on a surface 115 of the structure 101 by deposition of nucleating layer material, as described herein.

FIG. 2 illustrates a cross-sectional view of an example substrate 200, in accordance with some embodiments disclosed herein. In some examples, the substrate 200 is a compound semiconductor-containing substrate. Substrate 200 may include properties and/or elements similar to those described with respect to substrate 100 of FIG. 1. In some examples, a nucleating material 211 is added to an existing material of a structure 101 for preparing the structure 101 for diamond nucleation.

In some examples, the structure 101 may include the nucleating material 211. The nucleating material 211 is shown without a defined boundary with the structure 101, indicating that the nucleating material 211 may be added to the structure 101 during an epitaxial growth stage, for example, in a final stage of generating the structure 101. In some cases, instead of depositing a nucleating layer (e.g., 111) on the surface of the structure 101, the growth process of the structure 101 may be finalized by the addition of the nucleating material 211. In some cases, an area 213 near a surface of the structure 101 may include the nucleating material 211, and the surface of the nucleating material 215 may be prepared for diamond growth. The area 213 may comprise an interface between the nucleating material 211 and the structure 101 in addition to the interface between the diamond 103 and the nucleating material 211. The nucleating material 211 may be a crystalline material.

Diamond deposition is typically a high-temperature process often requiring temperatures greater than about 600° C. (e.g., 800° C.). Standard diamond growth practices typically include selecting such high temperatures, and other growth parameters, with the goal of achieving at least a minimum diamond quality threshold or achieving the highest diamond quality possible for improved thermal management of devices.

Diamond quality can be characterized by parameters including, but not limited to, thermal boundary resistance and average thermal conductivity. Thermal conductivity can be measured by laser flash or FTIR analysis, for example, at a temperature of about 23° C. Thermal boundary resistance can refer to the thermal resistance at the interface between two materials and can be measured by TDTR. TDTR can include the use of a pump pulse of laser light to heat an area on a target material. A probe pulse can measure the changes in reflectivity. A sample temperature may be calculated based on the changes in reflectivity and thermal boundary resistance may be calculated from decay in temperature. Thermal boundary resistances may be, for example, between about 7 and about 150 m² K/GW. Thermal boundary resistances may be greater than about 2 m² K/GW, greater than about 5 m² K/GW, greater than about 7 m² K/GW, greater than about 10 m² K/GW, greater than about 20 m² K/GW, greater than about 50 m² K/GW, greater than about 100 m² K/GW, greater than about 125 m² K/GW, or more. Thermal boundary resistances may be less than about 1000 m² K/GW, less than about 500 m² K/GW, less than about 250 m² K/GW, less than about 200 m² K/GW, less than about 150 m² K/GW, less than about 100 m² K/GW, less than about 50 m² K/GW, less than about 20 m² K/GW, less than about 10 m² K/GW, or less.

Interface quality may be characterized, for example, by an interface roughness, electrical conductivity, and mechanical interfacial toughness. Interface roughness may be measured or characterized by SEM of a cross-section of the device or by TEM of the interface. Mechanical interface toughness may be measured, for example, by ex situ nanoindentation induced buckling.

Growth direction and order of growth can influence interface quality and overall device performance. The growth direction of diamond or an epitaxially-grown semiconductor layer refers to the direction in which the thickness of a semiconductor layer or a diamond layer increases while such layers crystalize. After removing a semiconductor layer from a growth substrate, the growth direction of the freestanding semiconductor film may remain as a quality attribute or parameter. During diamond growth, surface roughness may increase as diamond thickness increases. Accordingly, the growth direction of diamond may also be an attribute or parameter to indicate diamond quality.

Growth parameters can include, for example, operating conditions associated with vapor deposition, such as temperature (° C.), pressure (Pa), and gas flow rate (standard cubic centimeters per minute (SCCM)) for introduction into a vapor deposition chamber. Chemical vapor deposition (CVD) can include, for example, hot filament vapor deposition or microwave plasma vapor deposition, among other vapor deposition formats. A flow rate may indicate an amount or rate of introduction of a carrier gas (e.g., hydrogen), a carbon-containing gas (e.g., methane) or another gas. A flow rate may be quantified in SCCM, as a percentage or as a ratio. For example, an amount or flow rate of a carbon-containing gas may be quantified as a percentage or ratio of an amount or flow rate of a carrier gas.

Growth parameters may also include a nitrogen flow rate, which may be quantified in SCCM or as a percentage or as a ratio of another amount or flow rate of gas. A nitrogen flow rate may be quantified as a percentage or ratio of an amount or flow rate of a carrier gas or of a carbon-containing gas. Nitrogen can be used in diamond growth to prevent damage to a material within a layered semiconductor structure. For example, nitrogen may prevent hydrogen from reacting with a GaN surface, as the hydrogen may replace nitrogen that is lost or separates from the GaN, keeping a GaN surface passivated during diamond growth.

Methods of manufacturing a compound semiconductor substrate may include identifying growth parameters based on one or more selected properties of such substrate. Such parameters can influence diamond growth conditions. Methods may include identifying such parameters based at least in part on an interface property of an interface or a surface property of a surface of the compound semiconductor substrate. Methods may include selecting the identified parameters for use in diamond growth. An interface may be formed between a semiconductor material layer (e.g., of a layered structure) and a diamond layer. Such interface may be formed by generating diamond on the material layer. The diamond may be generated in accordance with identified growth parameters. Such parameters may be identified and selected based on an amount of damage or defect to the material layer caused by diamond growth thereon. Such parameters may be identified and selected based on an amount of damage or defect to the material layer rather than being identified and selected based on a selected diamond quality.

An amount of damage may be quantified by an upper acceptable threshold of damage to material or by a minimum damage threshold value. Damage to a material may include etching or decomposition of the material structure.

Generating diamond using parameters that are selected based on damage to the material layer can result in lower quality diamond compared to diamond that is generated using standard diamond growth conditions, for example, parameters for high-quality diamond including temperatures exceeding about 600° C. or about 800° C. Methods of the present disclosure may include identifying or selecting growth parameters that include process temperatures below about 600° C. (e.g., temperatures from about 450° C. to about 600° C.).

The disclosed growth parameters may be used to manufacture a compound semiconductor substrate including a diamond layer disposed on a surface of a semiconductor-containing material layer, wherein the diamond layer and the semiconductor layer form an interface. In some examples, the interface is a single interface. In some examples, the diamond layer contacts (e.g., directly contacts) the semiconductor layer. In some examples, the diamond layer is operatively coupled to the semiconductor layer. Such compound semiconductor substrate may provide improved thermal conductivities and better performance compared to substrates having one or more intermediate layers (e.g., nucleating layers or interface layers) between the diamond and semiconductor layers (e.g., substrate 100 or 200).

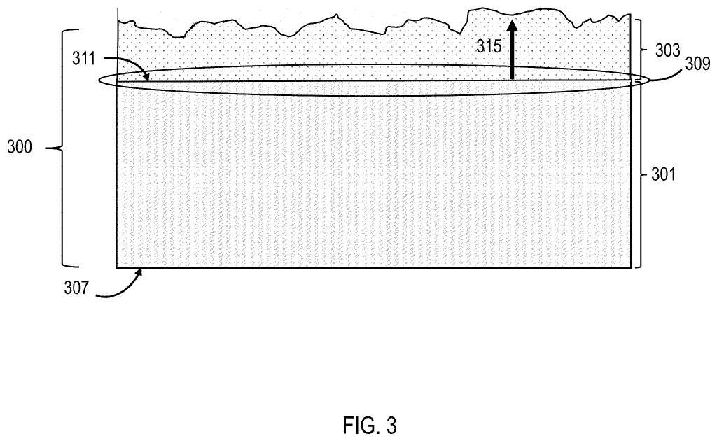

FIG. 3 illustrates a cross-sectional view of an example substrate 300, in accordance with some embodiments disclosed herein. The substrate 300 may be a compound semiconductor-containing substrate. Substrate 300 may be manufactured according to the methods described herein. Substrate 300 may include a semiconductor-containing structure 301 and at least one layer of carbon-containing material, such as synthetic diamond 303. The structure 301 may be a layered structure and may include a wide-bandgap semiconductor material. The wide-bandgap semiconductor material may be single-crystalline. The structure 301 may comprise a buffer layer. The structure 301 may comprise GaN. Substrate 300 is not shown to scale and may include magnified or exaggerated thicknesses and surface roughness.

In some examples, the structure 301 may be formed on a separate growth substrate (not shown), which may include silicon. The structure 301 may include transition layers (not shown). The transition layers may be formed proximal to growth substrate. In some examples, the structure 301 may be epitaxially grown on a first substrate, flipped and attached to a second substrate or carrier wafer (not shown). The first substrate may be removed from the structure 301. One or more layers of the structure 301 may also be removed (e.g., by etching or mechanical polishing), which may include transition layer(s). A surface of the structure 301 may be exposed for subsequent diamond growth. The exposed surface of the structure 301 may comprise GaN, for example, GaN only.

The diamond 303 may be generated over the structure 301, wherein the diamond 303 and the structure 301 form an interface. For example, at least one layer of the diamond 303 may be deposited over at least a portion of a layer or a surface 311 of the structure 301 at interface 309. The surface 311 of the structure 301 may be a backside surface of the structure 301. The diamond 303 may be generated on a surface of the structure 301 in the direction indicated by direction arrow 315 (e.g., from the structure 301 toward the diamond 303).

In some examples, the interface 309 can be a single interface between the diamond 303 and the structure 301. FIG. 1, for example, includes a nucleating layer 111 for nucleating growth of the diamond 103 on the surface 115 of the structure 101. FIG. 2, for example, includes nucleating material 211 for nucleating growth of the synthetic diamond 103 on the surface 213 of the structure 101. In both cases, at least nucleating material 211 or the nucleating layer 111 will separate the structure 101 from the synthetic diamond 103. In some cases, for example, the cases described in relation to FIG. 1 and FIG. 2 may include more than a single interface between the structure 101 and the synthetic diamond 103. For example, FIG. 1 and FIG. 2 may both include (1) an interface between the structure 101 and either the nucleating material 211 or the nucleating layer 111, and (2) another interface between either the nucleating material 211 or the nucleating layer 111 and the diamond 103.

Returning to FIG. 3, the interface 309 can be a single interface between the diamond 303 and the structure 301 that includes at least a portion of the diamond 303 in contact (e.g., direct contact) with at least a portion of the structure 301, and the interface 309 may form a boundary between the diamond 303 and the structure 301. Direct contact between the diamond 303 and the structure 301 at the interface 309 can include atoms of a material (e.g., GaN) of the structure 301 combining with atoms of the diamond 303. In some examples, the concentration of atoms at interface 309 includes substantially atoms of one type of material of the structure 301 and atoms of the diamond 303. In some examples, the interface 309 includes no atoms of a nucleating material (e.g., 211) or a nucleating layer (e.g., 111). In some examples, the concentration of atoms at the single interface 309 may include GaN atoms and diamond atoms, with substantially no other materials (e.g., amorphous or polycrystalline materials). In some examples, interface 309 may not include atoms of another material for the nucleation of the diamond 303, such as SiN, SiC or other silicon or wide-bandgap semiconductor materials used for nucleation of diamond. In some examples, additional semiconductor-containing material(s) may be grown on surface 307. In some examples, one or more barrier layers may be grown on surface 307. Further processing can include manufacturing of electronic or optical devices and circuits on the exposed surface of the structure 301.

In some examples, prior to generating the diamond 303, a surface of the structure 301 may be treated with ion implantation to reduce or eliminate electrical conductivity on the surface. Such methods can be also be performed on semiconductor substrates that include nucleating layers (e.g., FIGS. 1 and 2). Ions for implantation can include carbon ions and oxygen ions, for example. Such operations may not necessarily be in this order.

The diamond 303 may have a thermal conductivity that is greater than about 50 W/mK. In some examples, the diamond 303 may have a thermal conductivity from about 50 W/mK to about 500 W/mK. The thermal conductivity may be measured at a temperature of about 23° C. The diamond 303 may have a thickness of about 20 nanometers (nm) or less. The diamond 303 may have a thickness in a range from about 20 nm to about 2,000 nm. The diamond 303 may have a thickness of less than about 250 nm. The diamond 303 may have a thickness in a range from about 20 nm to about 2,000 nm, or from about 20 nm to about 10 microns. The roughness of the diamond 303 can vary, for example, depending on the duration of deposition and in some cases may have a roughness of about 7-8 nm. The interface 309 may have a roughness of about 1 atomic layer. The interface 309 may have a roughness of less than about 5 atomic layers, less than about 3 atomic layers, less than about 2 atomic layers, or less than about 1 atomic layer.

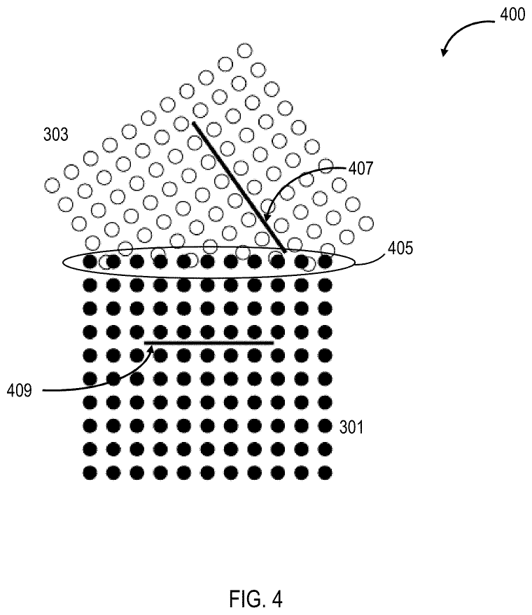

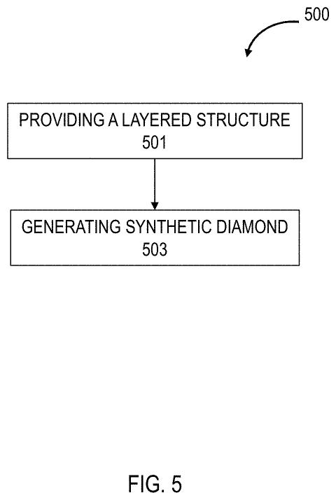

FIG. 4 illustrates an example material interface 400, in accordance with some embodiments disclosed herein. The interface 400 may be a single interface. The interface 400 is shown in FIG. 4 in a magnified manner to illustrate individual atoms of two materials. The interface 400 may include properties and/or elements similar to those described with respect to the interface 309 of FIG. 3 or FIG. 5. The interface 400 may be a variation, embodiment, or example of the interface 309 of FIG. 3. The interface 400 may include a carbon-containing material and a semiconductor. The interface 400 may include diamond and a wide-bandgap semiconductor. The wide-bandgap semiconductor may be GaN and may be single-crystalline.

Interface 400, in some examples, illustrates the diamond 303 directly contacting at least a portion of a layer of layered structure 301. As illustrated by the interface location 405, atoms of the diamond 303 combine with atoms of the layered structure 301 (e.g. GaN atoms). The interface location 405 may include substantially atoms of one semiconductor material of the layered structure 301 and atoms of the synthetic diamond 303, with no atoms of a nucleating material (e.g., 211) or a nucleating layer (e.g., 111).

The crystal structure orientations of the layered structure 301 are illustrated, for example, by the line 409. The crystal structure orientations of the diamond 303 are illustrated, for example, by the line 407. Line 409 and line 407 are positioned in different angles or directions help to illustrate two separate materials in direct contact at a single interface.

The example methods described with respect to FIG. 5 through FIG. 8 may include additional or even fewer operations or processes in comparison to what is illustrated in any of FIG. 5 through FIG. 8. Additionally, examples of the methods described with respect to FIG. 5 through FIG. 8 are not necessarily limited to the chronological order that is shown in such figures.

FIG. 5 illustrates generally a flowchart of an example method 500 of manufacturing a substrate, in accordance with some embodiments disclosed herein. In operation 501, a structure (e.g., layered structure) is provided. The structure may be, for example, the structure 301 of FIG. 3 or FIG. 4. In some examples, the structure is provided within a vapor deposition chamber. The structure may include a semiconductor-containing material. The structure may include a wide-bandgap semiconductor material. The wide-bandgap semiconductor material may be single-crystalline, for example, single-crystal GaN.

The structure may be epitaxially grown on a substrate, which may be a Si wafer or substrate. The structure may be attached to a carrier wafer or substrate, such as a Si carrier wafer or substrate, for example, after being epitaxially grown on a first substrate and flipped as described herein.

In operation 503, a carbon-containing material is generated over at least a portion of the structure in accordance with a set of growth parameters. In some examples, the carbon-containing material is synthetic diamond. In some examples, the carbon-containing material may be diamond-like, such as diamond-like carbon. In some examples, the carbon-containing material may be another material such as graphene, diamond nanoparticles or Nano diamond.

The carbon-containing material may comprise a layer of diamond or a portion of a layer of diamond. The diamond layer may be generated without the presence of a nucleation layer on the structure, for example, the diamond layer may be grown directly on the structure. The diamond layer may be grown, in part, using ultrasonic seeding.

The growth parameters may be generated prior to diamond growth and can define a set of growth conditions within a vapor deposition chamber. The set of growth parameters can include, for example, temperature (° C.), pressure (Pa), and gas (e.g., hydrogen, methane, or nitrogen) flow rate (SCCM). Growth parameters can also include operating conditions associated with diamond deposition in a hot filament reactor or a microwave reactor.

In some examples, the set of growth parameters are identified based at least in part on an interface property of an interface that is to be generated within or on the compound semiconductor substrate (e.g., 300). For example, the interface to be generated may be an interface (e.g., interface 309) between the structure 301 and a layer of the carbon-containing material (e.g., the diamond 303). The interface may be generated according to the set of growth parameters, and may be generated during growth of the carbon-containing material on the structure 301.

The set of growth parameters may include a grouping of any one or more of the growth parameters described herein. For example, the set may include temperature (° C.), flow rate of a carbon-containing gas and flow rate of a carrier gas (SCCM). The carbon-containing gas may include methane, carbon dioxide, or another carbon-containing gas. The carrier gas may include argon, hydrogen, or another carrier gas. The temperature may be about 450° C., about 600° C., less than about 600° C. or another temperature in a range from about 450° C. to about 600° C. The flow rate of the carrier gas may be about 2,000 SCCM, less than about 2,000 SCCM, a flow rate in a range from about 1,000 SCCM to about 5,000 SCCM, or another flow rate to achieve a particular process pressure in the chamber. The flow rate of the carbon-containing gas can be about 65 SCCM, less than about 65 SCCM or a flow in a range from about 0.5%-3.5% of an amount or flow rate of the carrier gas.

The interface property may be any one of the interface properties described herein, for example, charge density, thermal boundary resistance, thermal conductivity, electrical conductivity, electrical resistivity, and defect density. An interface property may include one or more other properties or values. The interface property may be a thermal conductivity of about 50 W/mK or greater, or a thermal conductivity in a range from about 50 W/mK to about 500 W/mK. The interface property may be a thermal boundary resistance less than about 15m² K/GW. For example, interface 309 may have a thermal boundary resistance less than about 15 m² K/GW.

The interface property may be a charge density less than or equal to about 1016 carriers/cm2. In some examples, a set of growth parameters may be identified based at least in part on a surface property, e.g., of a surface of the substrate 300. A surface property may include charge density, thermal boundary resistance, thermal conductivity, electrical conductivity, electrical resistivity, or defect density. In some examples, prior to diamond growth on a surface of the structure, the surface may be treated with ion implantation to reduce or eliminate electrical conductivity on the surface. Ion implantation may include the use of carbon, nitrogen, or oxygen ions, for example.

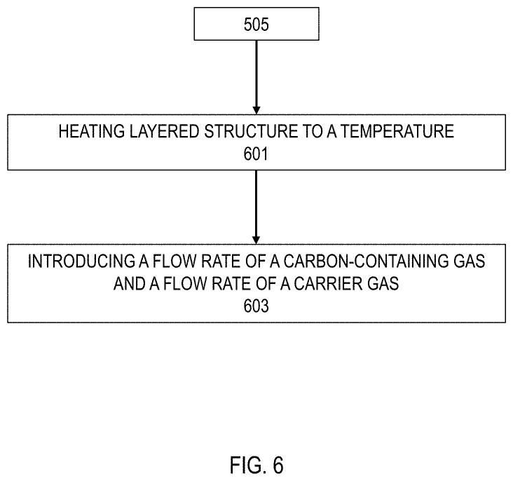

FIG. 6 illustrates generally a flowchart of an example method 505 of manufacturing a substrate. In some examples, the method 505 includes operations similar to FIG. 5. In some examples, the method 505 includes operations 501 and 503 of FIG. 5. At operation 601, the structure 301 is heated to a temperature (e.g., first temperature) for generating diamond. For example, the structure 301 may be heated to a temperature that is from about 450° C. to about 600° C. At operation 603, a flow of a carbon-containing gas and a flow of a carrier gas are introduced. The carbon-containing gas and the carrier gas may be any of the gases described herein. The carbon-containing gas and the carrier gas may not necessarily be introduced simultaneously.

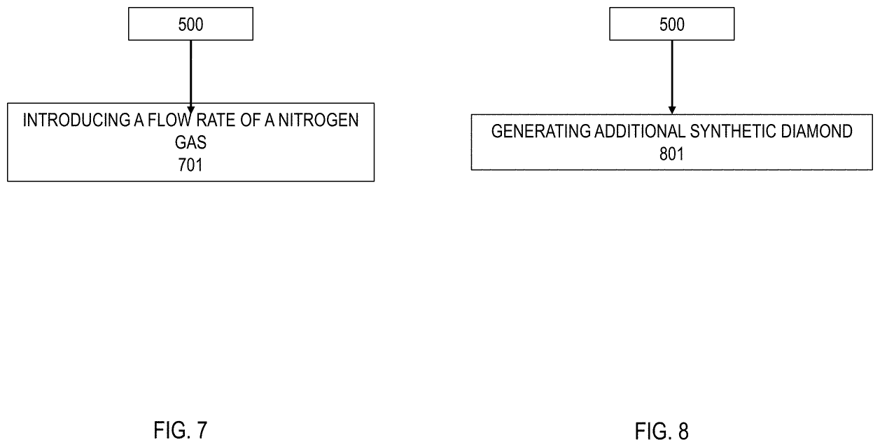

FIG. 7 illustrates generally a flowchart of an example method of manufacturing a substrate, in accordance with some embodiments disclosed herein. As shown in FIG. 7, the method 500 may include introducing a nitrogen gas, in operation 701. Hydrogen may etch a semiconductor-containing surface during diamond growth, for example, a surface including GaN. Such etching may cause the removal or loss of nitrogen and a build-up of metallic gallium on the GaN surface. Introducing a nitrogen gas may help avoid the formation of metallic gallium.

FIG. 8 illustrates generally a flowchart of an example method of manufacturing a substrate, in accordance with some embodiments disclosed herein. As shown in FIG. 8, the method 500 may include generating additional diamond in accordance with an additional set of growth parameters, in operation 901. The additional set of growth parameters may be generated prior to the additional diamond growth and may define a set of growth conditions within the vapor deposition chamber.

The additional set of growth parameters may be generated for use in generating diamond on the structure 301. The additional set of growth parameters can include, for example, temperature (° C.), pressure (Pa), and gas (e.g., hydrogen, methane or nitrogen) flow rate (SCCM). Growth parameters can also include operating conditions associated with diamond deposition in a hot filament reactor or a microwave reactor. The additional set of growth parameters can include a grouping of any one or more of the growth parameters described herein. For example, the additional set can include temperature (° C.), flow rate of a carbon-containing gas and flow rate of a carrier gas (SCCM). The carbon-containing gas can include methane, carbon dioxide, or another carbon-containing gas. The carrier gas can include argon, hydrogen, or another carrier gas. The additional set of growth parameters may be generated based at least in part on a thermal conductivity of the diamond to be generated in accordance with the additional or second set of growth parameters.

The structure 301 may be heated to a temperature (e.g., second temperature). For example, the structure 301 may be heated to a temperature that is equal to or greater than about 600° C. A flow of a carbon-containing gas and a flow of a carrier gas may be introduced. The carbon-containing gas and the carrier gas may be any of the gases described herein. The carbon-containing gas and the carrier gas may not necessarily be introduced simultaneously. The flow rate of the carrier gas may be about 2,000 SCCM, less than about 2,000 SCCM or another flow rate in a range from about 1,000 SCCM to about 5,000 SCCM. The flow rate of the carbon-containing gas may be about 65 SCCM, less than about 65 SCCM or in a range from about 0.5%-3.5% of an amount or flow rate of the carrier gas.

The additional diamond can be an additional layer of diamond that is generated over an existing layer of diamond, wherein the existing layer of diamond is generated in accordance with the first set of growth parameters. The additional diamond and the existing diamond may be together represented as the diamond 303 in FIG. 3 or FIG. 4. In some examples, the existing diamond may be represented by the diamond 303, and the additional diamond may be separate from 303 and not shown. In some examples, 303 represents the additional diamond and the existing diamond without a distinct boundary or interface between the additional diamond and the existing diamond. The additional diamond may have a thermal conductivity that is greater than about 1000 W/mK. The additional diamond may have a thickness of about 500 micrometers or less, or a thickness of about 2,000 micrometers or less.

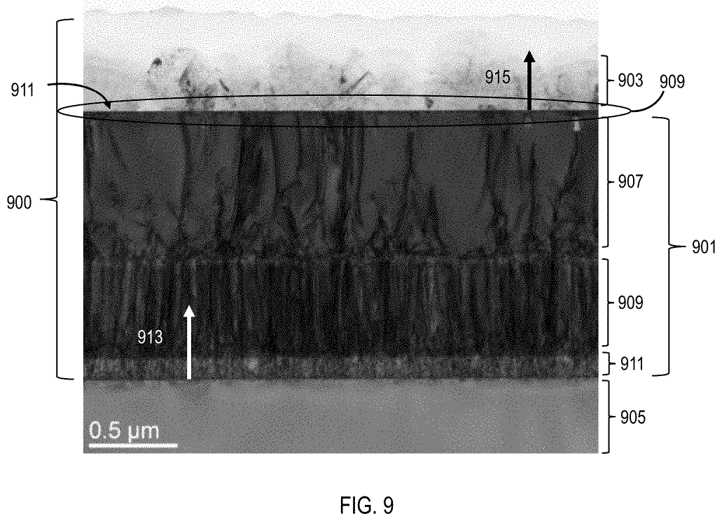

FIG. 9 illustrates a cross-sectional view of an example substrate 900, in accordance with some embodiments disclosed herein. In some examples, the substrate 900 is a compound semiconductor-containing substrate. FIG. 9 may illustrate a TEM micrograph of the example substrate 900. The methods described herein with respect to FIG. 5 through FIG. 8 may be used to manufacture the substrate 900. The substrate 900 may include properties and/or elements similar to those described with respect to substrate 300 of FIG. 3 or FIG. 4.

The substrate 900 may include diamond that has been generated over a layered structure that has not been flipped, for example, the structure may remain on the substrate upon which it was epitaxially grown. The substrate 900 includes a semiconductor-containing layered structure 901 and at least one layer of diamond 903, and substrate 900 is disposed on a silicon wafer or substrate 905, which may be removed to expose a surface of the structure 901. The substrate 905 and the transition layer(s) (e.g., 911, 909) may be etched or ground to expose at least part of a surface of the structure 901 for further processing. In some examples, additional material may be grown or deposited on the exposed surface of the structure 901, for example, a wide-bandgap semiconductor material. The structure 901 may include at least one layer of at least one wide-bandgap semiconductor material, such as GaN. The structure 901 may include one or more of AlGaN, InGaAlN, Ga2O3 and derivatives thereof. The wide-bandgap semiconductor material may be single-crystalline.

The structure 901 may be epitaxially grown in the direction indicated by growth direction arrow 913. The diamond 903 may be generated over a surface of the structure 901 in the direction indicated by direction arrow 915. At least one layer of the diamond 903 may be deposited over at least a portion of a layer or a surface 911 of the structure 901, forming an interface 909 between the diamond 903 and the structure 901, which may be a single interface.

The structure 901 may comprise GaN that has a lattice constant different from a lattice constant of the substrate 905 and the structure 901 may include multiple layers of semiconductor-containing materials (e.g., GaN and AlN). The multiple layers may include a buffer layer 907 and transition layer(s) (e.g., 909, 911). The multiple layers may include AlN or a combination of GaN and AlN.

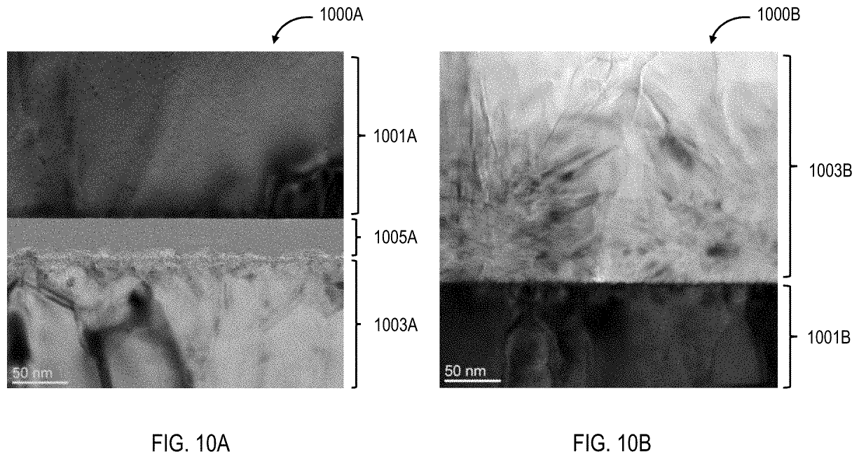

FIG. 10A illustrates a cross-sectional view of an example substrate 1000A, in accordance with some embodiments disclosed herein. In some examples, the substrate 1000A is a compound semiconductor substrate. FIG. 10 may illustrate a TEM micrograph of the substrate 1000A. The substrate 1000A may include a layered semiconductor-containing structure 1001A, a layer of diamond 1003A, and an intermediate layer 1005A (e.g., amorphous or polycrystalline protection or nucleating layer) disposed between the structure 1001A and the layer of diamond 1003A.

FIG. 10B illustrates a cross-sectional view of an example substrate 1000B, in accordance with some embodiments disclosed herein. In some examples, the substrate 1000B is a compound semiconductor-containing substrate. The substrate 1000B may be a magnified view of substrate 900 (e.g., interface 909). The substrate 1000B may include a layered semiconductor-containing structure 1001B and diamond 1003B. In contrast to substrate 1000A, substrate 1000B does not have an intermediate (e.g., amorphous or polycrystalline protection or nucleating layer) layer between the layered structure 1001B and the diamond 1003B. The substrate 1000B may include a single interface between the diamond 1003B and the structure 1001B, which may have properties and/or elements similar to any of interfaces 909, 400 and 309.

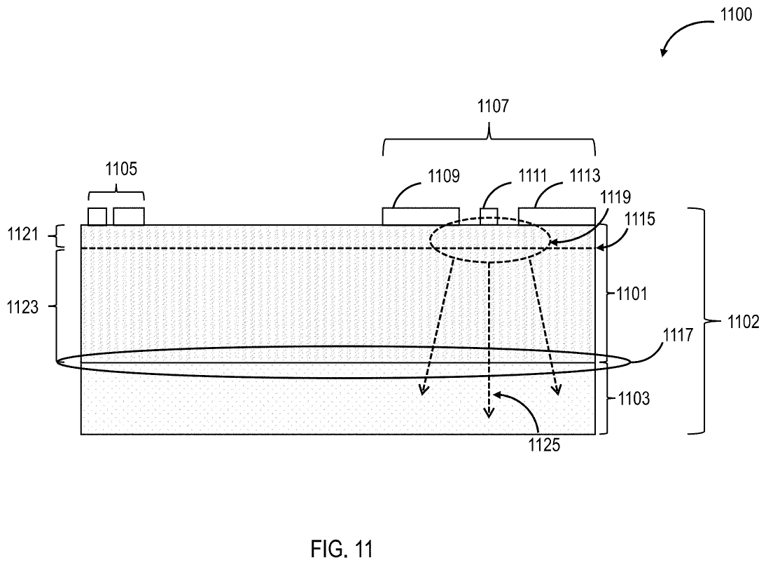

FIG. 11 illustrates a cross-sectional view of an example substrate 1100, in accordance with some embodiments disclosed herein. In some examples, the substrate 1100 is a compound semiconductor-containing substrate. The substrate 1100 may include properties and/or elements similar to any of substrate 300, interface 400 and interface 909. Substrate 1100 may comprise a monolithically integrated microwave or millimeter-wave circuit (MMIC), such as a MMIC chip 1102. In some examples, the chip 1102 can comprise a structure 1101 that includes at least one layer of a wide-bandgap semiconductor material. The structure 1101 may include similar properties and/or elements to the layered structure 301. The wide-bandgap semiconductor material may be single-crystalline. The chip 1102 may also include at least one layer of diamond 1103. The chip 1102 may be attached to a package base (not shown), for example, below the synthetic diamond 1103.

The chip 1102 may comprise electrical connections, a passive circuit 1105 and an active circuit 1107 disposed on a surface of the layered structure 1101. Active circuit 1107 may be a transistor, as described herein, and may comprise a source 1109, gate 1111, and drain 1113 terminals disposed on structure 1101. The structure 1101 may include a two-dimensional electron gas layer or source (2DEG) 1115, which may be embedded within the structure 1101. The structure 1101 and the diamond 1103 may be in contact at a single interface 1117. Transistor 1107 may use a voltage applied between the gate 1111 and the source 1109 to control the current flowing along the 2DEG 1115 between the source 1109 and the drain 1113. The region 1119 of the 2DEG where the gate voltage controls the current is below the gate 1111. A barrier layer 1121, a buffer layer 1123 or both may be adjacent to the 2DEG and together they may form the structure 1101.

During the operation of transistor 1107, heat may be generated in the region 1119 (e.g., active region). Generally, a transistor's thermal efficiency can be limited by its ability to conduct heat away from an active region to the transistor's substrate and external environment. For example, the thermal efficiency of transistor 1107 may depend at least in part on the ability of the chip 1102 to conduct heat away from region 1119 through the structure 1101 and the diamond 1103. The chip 1102 may conduct heat away from the region 1119 to an external environment, e.g., via the layered structure 1101, the diamond 1103 and a package base (not shown). Heat may additionally transfer from a package base into a heat conducting element (not shown). The heat spreading and direction of flow is indicated with arrows 1125. An objective of an efficient transistor-chip thermal design is to reduce thermal resistance between a heat source (e.g., region 1119) and a package base. Thermal resistance may be defined as a difference between a peak temperature of a heat generating region 1119 and an average temperature of a back surface of a package base, divided by the power dissipated during normal operation. Substrate 1100, not including nucleating layer(s), may provide reduced thermal resistance between the region 1119 and a package base (not shown).

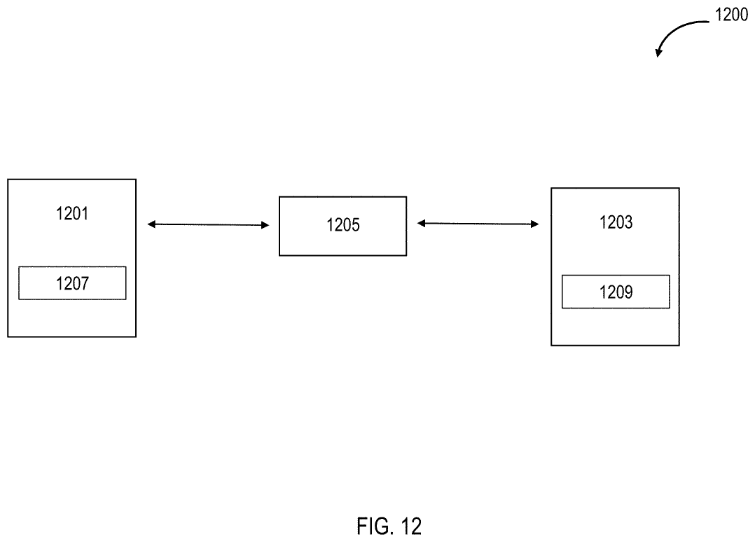

FIG. 12 illustrates a block diagram of an example system 1200 including one or more devices that comprise a semiconductor-containing substrate, in accordance with some embodiments disclosed herein. System 1200 may be a wireless system, for example, a wireless communication system (e.g., radio-frequency (RF), microwave, free-space optical) or a wireless power transfer system. System 1200 includes device 1201, device 1203 and link 1205. Device 1201 and device 1203 may be configured to communicate wirelessly over link 1205. Link 1205 may comprise wireless communications (e.g., electromagnetic signals) between device 1201 and device 1203 and may be characterized by parameters including path loss. In examples where system 1200 is not a wireless system, link 1205 may be a cable (e.g., electrical conductor or optical fibers). Device 1201, device 1203, or both may include circuitry or components comprising substrates similar to substrate 300, substrate 900, substrate 1100, or other substrates manufactured according to the methods described herein. By comprising such substrates, devices 1201 and 1203 may provide improvements in wireless communications through, at least, improved device thermal efficiencies and power-added efficiencies (PAE).

Device 1201 may include a transmitter 1207 for transmitting electromagnetic signals to device 1203. Device 1203 may include a receiver 1209 for receiving electromagnetic signals from device 1201. Transmitter 1207 may be an RF or microwave transmitter, including transmitting circuitry configured to be communicatively coupled to one or more antennas, for transmitting RF or microwave signals over link 1205 to device 1203. In some examples, transmitter 1207 may be an optical transmitter, communicatively coupled to optical transmitting circuitry and components, for transmitting optical signals over link 1205 to device 1203. Receiver 1209 may be an RF or microwave receiver, including receiving circuitry configured to be communicatively coupled to one or more antennas, for receiving RF or microwave signals over link 1205 from device 1201. Device 1201 and device 1203 may also include circuitry configured for both transmitting and receiving functions (e.g., transceiver).

Device 1201 and device 1203 may also include components such as processor(s), memory, input device(s), output controller(s), signal generation device(s), network interface device(s), sensor(s), and power source(s), which some or all may communicate with each other via an interlink (e.g., bus). Device 1201 and device 1203 may be terrestrial or aerial devices, and may be stationary or mobile. Nonlimiting examples of stationary devices include, for example, land stations (e.g, base station, node, access point) or ground stations (e.g., earth station, terminal, gateway). Nonlimiting examples of mobile devices include, for example, vehicular devices, aerial devices or mobile client devices. Device 1201 or device 1203 (or both) may be a satellite, such as a cubesat or a microsat.

System 1200 may be part of, or may be configured for communication with, a wireless network such as a satellite network, a cellular network or a noncellular network. A satellite network can include, for example, a Low Earth Orbit (LEO) satellite network, a Geostationary (GEO) satellite network or a Medium Earth orbit (MEO) satellite network. A noncellular network can include, for example, a local area network (LAN), a wide area network (WAN) or a packet data network. A cellular network (e.g., radio access network) can include, for example, a 3rd Generation Partnership Project (3GPP) Long Term Evolution (LTE), 5th Generation (5G) New Radio, or Internet-of-Things (IoT) network. A network may include network devices, such as routing apparatuses, network routers or network switches (not shown). Device 1201 and device 1203 may be configured to use or interface with one or more communication protocols, for example, Digital Video Broadcasting—Satellite (DVB-S) protocol, Consultative Committee for Space Data Systems (CCSDS) protocol, Transmission Control Protocol/Internet Protocol (TCP/IP), Institute of Electrical and Electronics Engineers (IEEE) protocols, 3GPP, 5G and European Telecommunications Standards Institute (ETSI) protocols.

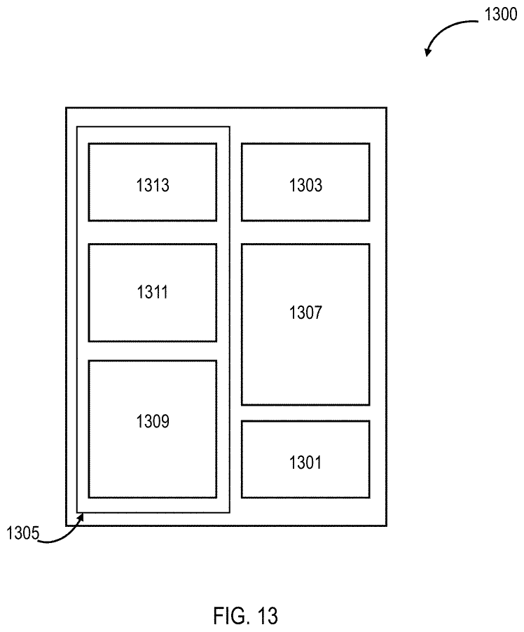

FIG. 13 illustrates a block diagram of an example wireless device 1300, in accordance with some embodiments disclosed herein. Device 1300 may include similar properties and/or elements to device 1201 or device 1203. Aspects may include or operate by logic, components or mechanisms in device 1300. Circuitry may be defined as a collection of circuits implemented in tangible entities of device 1300, including hardware (e.g., simple circuits, gates, logic). Circuitry of device 1300 can include components that are configured to perform the operations of the methods described herein. Circuitry of device 1300 may be hardwired (e.g., hardware circuitry of device 1300) to carry out the operations. Hardware circuitry of device 1300 may include communicatively coupled physical components (e.g., execution components, transistors, simple circuits) including a machine-readable or computer-readable medium that may be physically modified (e.g., magnetically, electrically) to encode instructions of the operations.

In one aspect, device 1300 is a satellite (e.g., cubesat, microsat), for example, within a satellite communication network. Device 1300 may comprise energy block 1301, which may comprise one or more solar cells and a battery, a waste heat radiator 1303, a control-communications block 1305, and a payload 1307. Device 1300 may include additional components which are not shown. In some examples, the payload 1307 may include sensing, measurement or imaging instrumentation. The control-communications block 1305 may comprise a transmitter 1309, a receiver 1311, and control circuitry 1313 (e.g., for managing control functions of the components of device 1300). The components of the device 1300 may be communicatively coupled via an interlink (e.g., bus).

Transmitter 1309 may be an RF or microwave transmitter, including transmitting circuitry configured to be communicatively coupled to one or more antennas, for transmitting RF or microwave signals over a wireless link to another device (e.g., another satellite, ground station). Receiver 1311 may be an RF or microwave receiver, including receiving circuitry configured to be communicatively coupled to one or more antennas, for receiving RF or microwave signals over a wireless link from another device (e.g., ground station or another satellite). In some examples, transmitter 1309 may comprise a MMIC chip, similar to MMIC chip 1102. Transmitter 1309 (or receiver 1311) may include circuitry or components comprising substrates similar to substrate 300, 900, 1100, or other substrates manufactured according to the methods described herein.

Such substrates contribute to efficient thermal management and improved PAE of the device 1300. Energy consumption (e.g., subsequent heat dissipation) of transmitter 1309 may increase with a data transfer rate according to the Shannon-Hartley theorem. A minimum size of device 1300 may be determined by dimensions of transmitter 1309 and whether device 1300 can produce sufficient power to operate the transmitter 1309. This in turn can be a determining factor in a link budget. For example, power dissipated in the transmitter 1309 may be greater than a sum of powers dissipated in the control circuitry 1313 and the receiver 1311 combined, particularly if the device 1300 is configured to communicate in a high-frequency band (e.g., mmWave, K-band).

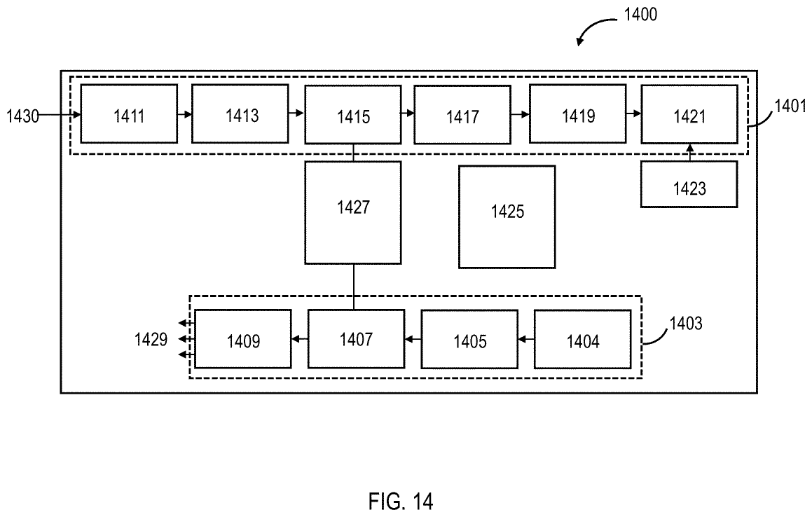

FIG. 14 illustrates a block diagram of an example control-communications block 1400 of a wireless device, in accordance with some embodiments disclosed herein. Control-communications block 1400 may include similar properties and/or elements to control-communications block 1305, and may include additional components not shown in FIG. 14. Control-communications block 1400 may include circuitry or components comprising substrates similar to substrate 300, 900, 1100, or other substrates manufactured according to the methods described herein. Control-communications block 1400 may include transmitting circuitry (e.g., transmitting circuitry 1401), configured to be communicatively coupled to one or more antennas, for transmitting RF or microwave signals. Control-communications block 1400 may also include receiving circuitry (e.g., receiving circuitry 1403) configured to be communicatively coupled to one or more antennas, for receiving RF or microwave signals. In some examples, the receiving circuitry 1403 may comprise a radio front end of a device, such as device 1300.

The receiving circuitry 1403 can include a low-noise amplifier (LNA) 1404, a bandpass filter 1405, a frequency downconverter 1407, and a demodulator 1409. The output of the receiving circuitry 1429 may be transmitted to a modulator or an on-board computer (OBC) (not shown). In some examples, the receiving circuitry 1403 may have additional components, not shown in FIG. 14. The transmitting circuitry 1401 can include a modulator 1411, a low-pass filter (e.g., anti-aliasing filter (AAF)) 1413, a mixer 415, a bandpass filter 417, a variable gain amplifier 1419 (e.g., including a gain-commanding function), and a power amplifier (e.g., solid-state power amplifier SSPA) 1421. In some examples, the transmitting circuitry 401 may have additional components not shown in FIG. 14. Control-communications block 1400 may also include a sequence generator 1423, DC power conditioning circuitry 1425 and frequency synthesis circuitry 1427, which may include a local oscillator (LO) or LO function. Some or all of the components shown in control-communications block 1400 (including those not shown) may communicate with each other via an interlink (e.g., bus) (not shown).

In some examples, the receiving circuitry 1403 may receive an RF signal (e.g., from an antenna of the device 1300). The received RF signal may be transmitted from a ground station or another device (e.g., satellite). The LNA 1404 may amplify the received RF signal, the bandpass filter 1405 may filter the signal to a frequency of interest, the frequency downconverter 1407 may downconvert the filtered RF signal to another frequency (e.g., as used by the frequency synthesis circuitry 1427) for processing of the signal (e.g., removing an RF carrier wave signal to produce an intermediate frequency (IF) signal for processing), and the demodulator 1409 may decode the down-converted signal to extract an information-bearing signal.

In some examples, the transmitting circuitry 1401 may prepare a signal (e.g., RF signal, satellite signal) for transmission to another device (e.g., satellite, ground station). The modulator 1411 may produce an analog baseband information signal from a digital information signal (e.g., provided by another component and input at 1430). The low-pass filter or AAF 1413 may filter the analog signal to remove aliasing from the digital-to-analog conversion. The mixer 1415 may prepare the signal for transmission on an RF carrier wave by mixing the analog baseband signal with an RF signal, for example, an RF signal provided by the frequency synthesis circuitry 1427. The bandpass filter 1417 may filter the resulting RF information signal to a transmission frequency of interest and variable gain amplifier 1419 may provide the RF information signal at a specified gain to an input of the SSPA 1421. The SSPA 1421 may amplify the RF information signal for transmission by one or more antennas of the device (e.g., device 1300). In some examples, the SSPA 1421 may comprise a MMIC chip, similar to MMIC chip 1102. The sequence generator 1423 may generate sequences for the input of the SSPA 1421. For example, the sequence generator 1423 may generate a sequence (e.g., at a specified voltage) for the gate terminal of the MMIC chip and a sequence for the drain terminal of the MMIC chip. DC power conditioning circuitry 1425 may convert a battery supply voltage (e.g., a voltage provided by energy block 1301) to a bias voltage for the components of the control-communications block 1400.

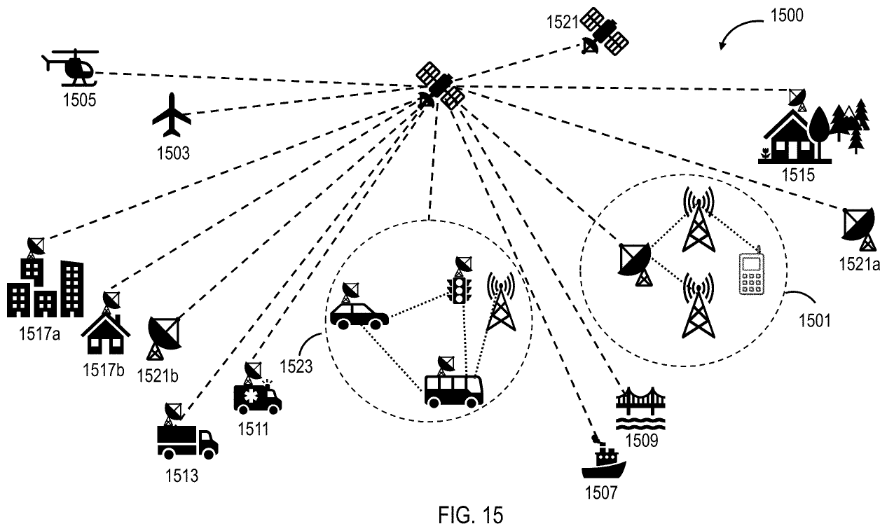

FIG. 15 illustrates a block diagram representing various example wireless communication networks 1500, in accordance with some embodiments disclosed herein. In some examples, FIG. 15 illustrates various applications of devices that comprise circuitry or components comprising substrates similar to substrate 300, 900, 1100, or other substrates manufactured according to the methods described herein. Such devices may operate with greater thermal efficiency and power added efficiency (PAE) in comparison to alternative devices that do not include such substrates. Such devices can provide improved RF performance and increased network capacity compared to alternative devices, while reducing a need for complex thermal control systems. Applications of such devices can include, but are not limited to, cellular backhaul over satellite 1501, aeronautical satellite communications (e.g., internet over satellite for aviation 1503, emergency and safety 1505), maritime satellite communications 1507, infrastructure monitoring 1509, land-based emergency and disaster relief 1511, highly-distributed networks 1513 (e.g., asset tracking), network connectivity alternatives for remote areas 1515 or urban areas 1517a and 1517b, satellite communications (e.g. satellite to satellite 1521 and ground station to satellite 1525a and 1525b), and IoT networks 1523. FIG. 15 does not fully illustrate each and every network link or device within each of the aforementioned wireless communication network applications. For each application, additional wireless and/or wired links and devices may be present in a network.

The devices described herein (e.g., 1201, 1203) may be satellite communications devices (e.g., satellites) capable of operating at many different frequencies and communication bands as part of a satellite communication system. For example, such devices may operate in an L-band frequency range (e.g., 1-2 GHz), S-band frequency range (e.g., 2-4 GHz), C-band frequency range (e.g., 4-8 GHz), X-band frequency range (e.g., 8-12 GHz), K-band frequency range (e.g., 17-20 GHz (Ku/K-bands), 37-40 GHz (Ka-bands)), a V-band frequency range (e.g., 40-75 GHz), W-band frequency range (e.g., 75-110 GHz), mm-wave band frequency range, G-band frequency range (e.g., 110-300 GHz), E-band frequency range (e.g., 60-90 GHz), or other frequency ranges.

In some examples, a device is a satellite that may be configured to operate in a Ka-band at a frequency in a range from about 18.3 GHz to about 20.2 GHz (e.g, 18.3 GHz). The satellite may be positioned, as part of a satellite constellation, at an altitude between about 400 km and about 600 km (e.g., 500 km). The satellite may transmit communications signals at an RF power of about 10 W, 20 W or 50 W (e.g., 10 W) and may have a noise power ratio between about 15 dB to about 30 dB (e.g., 30 dB). At least one antenna may be communicatively coupled to the satellite. The antenna may have a cross-polarization isolation (XPI) of 22 dB. The antenna may have a diameter in a range from about 0.45 meters to about 1.2 meters (e.g., 0.5 meters). The antenna may have a diameter in a range from about 2 meters to about 5 meters. The antenna may have an efficiency of about 0.45. The antenna may have a gain of about 36.16 dBi. Antenna gain may be influenced by factors such as antenna efficiency, antenna diameter and the wavelength of the transmitted signal. The pointing error may be about 1.0 degrees. For these values, the transmitter may transmit with an EIRP of about 43.88 dBW.

In some examples, an elevation angle (e.g., between the satellite and a horizontal plane) may be a value in a range from about 15 degrees to about 25 degrees (e.g., 20 degrees). The path length may be about 1193 km. In some examples, free space path loss may be about 179.22 dB. Atmospheric gas losses may be about 1.5 dB or within a range from about 0 dB to about 10 dB. The expected loss due to rain fade may be about 20 dB. The total propagation loss can include the sum of the free space path loss and the environmental losses, such as atmospheric gas losses and rain fade, and may equal about 200.72 dB. The gain at the receiver contributes to the strength of the signal and may be dependent on the geometry of the receiver antenna. The diameter of the receiver antenna may be in a range from about 10 meters to about 20 meters (e.g., 13.2 meters). In such example, the antenna efficiency may be about 0.6 and the antenna gain may be about 65.84 dBi.

The receiver may also introduce signal loss. The pointing loss at the receiver may be about 0.2 dB. The XPI loss may be about 25 dB. The temperature of the antenna may be about 75 K. The receiver low noise amplifier (LNA) noise figure may be about 2 dB. The LNA noise effective temperature may be about 169.62 K, which may be influenced by noise factor. The feeder operating temperature may be about 300 K. The feeder and input filter loss may be about 1 dB. The effective system noise temperature may be about 290.90 K. The receiver gain over temperature may be about 40.01 dB/K. In some examples, the satellite may be allocated a bandwidth of about 1200 MHz. The roll-off factor for the transmitter may be about 0.1. The roll-off factor may be between about 0 and about 0.4. The symbol rate may be about 1090.91 Msym/sec. Using a modulation scheme of 128 APSK, the symbol rate may correspond to 7 bits per symbol. The code rate may be about 0.8. The overhead may be about 0.1. The sums of the gains and losses at the transmitter and receiver may total about −102.2 dB. For a transmitter power of 10 dBW, a carrier signal power may be about −92.2 dBW. The noise signal may be about −113.58 dBW and may be influenced by the noise temperature and the symbol rate. The carrier-to-noise ratio (CNR) may be about 21.39 dBm, which may vary when losses from XPI and noise power ratio are considered (e.g., 17.51 dB). The Shannon capacity may be about 7.01 Gbps. In some examples, the Shannon capacity may be about 5.05 Gbps, for example, when coding and overhead are considered. The dB factor away from Shannon may be 3 dB. The data rate may be about 5.84 Gbps. Data rate may be influenced by factors such as bandwidth, CNR and the dB factor in linear space. Accounting for coding and overhead, the data rate may be about 4.21 Gbps.

In another example, a device is a satellite that may be configured to operate at a frequency of about 42 GHz. The satellite may be positioned, as part of a satellite constellation, at an altitude between about 400 km and about 600 km (e.g., 500 km). The satellite may transmit communications signals at an RF power of about 5 W, 10 W, 20 W or 50 W (e.g., 5 W) and may have a noise power ratio between about 15 dB to about 30 dB (e.g., 15 dB). At least one antenna may be communicatively coupled to the satellite. The antenna may have a cross-polarization isolation (XPI) of about 22 dB. The antenna may have a diameter in a range from about 0.45 meters to about 1.2 meters (e.g., 0.5 meters). The antenna may have a diameter in a range from about 2 meters to about 5 meters. The antenna may have an efficiency of about 0.45 and a gain of about 43.4 dBi. The pointing error may be about 1.0 degrees. For these values, the transmitter may transmit with an EIRP of about 47.37 dbW.

In some examples, an elevation angle (e.g., between the satellite and a horizontal plane) may be a value in a range from about 15 degrees to about 25 degrees (e.g., 20 degrees). The path length may be about 1193 km. In some examples, free space path loss may be about 86.44 dB. Atmospheric gas losses may be about 1.5 dB or within a range from about 0 dB to about 10 dB. The expected loss due to rain fade may be about 20 dB. The total propagation loss can include the sum of the free space path loss and the environmental losses, such as atmospheric gas losses and rain fade, and may equal about 212.94 dB. The gain at the receiver contributes to the strength of the signal and may be dependent on the geometry of the receiver antenna. The diameter of the receiver antenna may be about 12 meters or may be within a range from about 10 meters to about 20 meters. In such example, the antenna efficiency may be about 0.6 and the antenna gain may be about 72.23 dBi.

The receiver may also introduce signal loss. The pointing loss at the receiver may be about 0.2 dB. The XPI loss may be about 25 dB. The temperature of the antenna may be about 75 K. The receiver low noise amplifier (LNA) noise figure may be about 2 dB. The LNA noise effective temperature may be about 169.62 K and may be influenced by factors including noise factor. The feeder operating temperature may be about 300 K. The feeder and input filter loss may be about 1 dB. The effective system noise temperature may be about 290.90 K. The receiver gain over temperature may be about 46.39 dB/K. In some examples, the satellite may be allocated a bandwidth of about 2000 MHz. The roll-off factor for the transmitter may be about 0.1. The roll-off factor may be between about 0 and about 0.4. The symbol rate may be about 1818.18 Msym/sec. Using a modulation scheme of 128 APSK, the symbol rate may correspond to 7 bits per symbol. The code rate may be about 0.8. The overhead may be about 0.1. The sums of the gains and losses at the transmitter and receiver may total about −101.53 dB. For a transmitter power of 10 dBW, a carrier signal power may be about −94.54 dBW. The noise signal may be about −111.37 dBW and may be influenced by such factors as the noise temperature and the symbol rate. The CNR may be about 16.82 dB, which may vary when losses from XPI and noise power ratio are considered. The Shannon capacity may be about 8.2 Gbps. In some examples, the Shannon capacity may be about 5.91 Gbps, for example, when coding and overhead are considered. The dB factor away from Shannon may be 3 dB. The data rate may be about 6.37 Gbps. Accounting for coding and overhead, the data rate may be about 4.59 Gbps.

In another example, a device is a satellite that may be configured to operate at a frequency of about 42 GHz. The satellite may be positioned, as part of a satellite constellation, at an altitude between about 5000 km and about 7000 km (e.g., 6000 km). The satellite may transmit communications signals at an RF power of about 5 W, 10 W, 20 W or 50 W (e.g., 5 W) and may have a noise power ratio between about 15 dB to about 30 dB (e.g., 30 dB). The XPI may be about 22 dB. The antenna may have a diameter in a range from about 0.45 meters to about 1.2 meters (e.g., 0.5 meters). The antenna may have a diameter in a range from about 2 meters to about 5 meters. The antenna may have an efficiency of about 0.45. The antenna may have a gain of about 43.4 dBi. The pointing error may be about 1.0 degrees. For these values, the transmitter may transmit with an EIRP of 47.37 dBW.

In some examples, an elevation angle (e.g., between the satellite and a horizontal plane) may be a value in a range from about 15 degrees to about 25 degrees (e.g., 20 degrees). The path length may be about 1193 km. In some examples, free space path loss may be about 86.44 dB. Atmospheric gas losses may be about 1.5 dB or within a range from about 0 dB to about 10 dB. The expected loss due to rain fade may be about 25 dB (e.g., heavy rain). The total propagation loss can include the sum of the free space path loss and the environmental losses, such as atmospheric gas losses and rain fade, and may equal about 230.15 dB. The gain at the receiver contributes to the strength of the signal and may be dependent on the geometry of the receiver antenna. The diameter of the receiver antenna may be in a range from about 10 meters to about 20 meters (e.g., 12 meters). In such example, the antenna efficiency may be about 0.6 and the antenna gain may be about 72.23 dBi.

The receiver may also introduce signal loss. The pointing loss at the receiver may be about 0.2 dB. The XPI loss may be about 25 dB. The temperature of the antenna may be about 75 K. The receiver low noise amplifier (LNA) noise figure may be about 2 dB. The LNA noise effective temperature may be about 169.62 K. The feeder operating temperature may be about 300 K. The feeder and input filter loss may be about 1 dB. The effective system noise temperature may be about 290.90 K. The receiver gain over temperature may be about 46.39 dB/K. In some examples, the satellite may be allocated a bandwidth of about 250 MHz. The roll-off factor for the transmitter may be about 0.1. The roll-off factor may be between about 0 and about 0.4. The symbol rate may be about 227.27 Msym/sec. Using a modulation scheme of 128 APSK, the symbol rate may correspond to 7 bits per symbol. The code rate may be about 0.8. The overhead may be about 0.1. The sums of the gains and losses at the transmitter and receiver may total about −118.74 dB. For a transmitter power of 10 dBW, a carrier signal power may be about 31 111.75 dBW. The noise signal may be about -120.40 dBW. The CNR may be about 8.65 dB, which may vary when losses from XPI and noise power ratio are considered (e.g., 8.33 dB). The Shannon capacity may be about 0.74 Gbps. In some examples, the Shannon capacity may be about 0.53 Gbps, for example, when coding and overhead are considered. The dB factor away from Shannon may be 3 dB. The data rate may be about 0.54 Gbps. Accounting for coding and overhead, the data rate may be about 0.39 Gbps

In one example, a device is a satellite that may be configured to operate in a Ka-band at a frequency in a range from about 17.7 GHz to about 20.2 GHz. The satellite may be positioned, as part of a satellite constellation, at an altitude between about 5000 km and about 7000 km (e.g., 6000 km). The satellite may transmit communications signals at an RF power between about 200 W to about 400 W (e.g., 300 W) and may have a noise power ratio between about 15 dB to about 30 dB (e.g., 15 dB). The cross-polarization discrimination (XPD) may be greater than about 15 dB. The antenna gain may be about 38 dBi to about 42 dBi (e.g., 40 dBi). The satellite may be allocated a bandwidth of about 20 GHz. The total capacity of the satellite communication system may be at least about 50 Gbps.

In one example, a device is a satellite that may be configured to operate in an E-band at a frequency in a range from about 71 GHz to about 76 GHz. The satellite may be positioned, as part of a satellite constellation, at an altitude between about 400 km and about 600 km (e.g., 500 km). The satellite may transmit communications signals at an RF power of about 40 W. The satellite transmitter may have a noise power ratio of about 15 dB. The XPI may be about 18 dB.

While various embodiments of the present invention have been shown and described herein, it will be obvious to those skilled in the art that such embodiments are provided by way of example only. It is not intended that the invention be limited by the specific examples provided within the specification. While the invention has been described with reference to the aforementioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations or relative proportions set forth herein which depend upon a variety of conditions and variables. It should be understood that various alternatives to the embodiments of the invention described herein may be employed in practicing the invention. It is therefore contemplated that the invention shall also cover any such alternatives, modifications, variations, or equivalents. It is intended that the following claims define the scope of the invention and that methods and structures within the scope of these claims and their equivalents be covered thereby.

1.-23 (canceled)

24. A semiconductor apparatus comprising:
a layered structure including a wide-bandgap semiconductor material; and
at least one layer of synthetic diamond disposed over and in contact with at least a portion of the layered structure at an interface, wherein a thermal conductivity of the at least one layer of synthetic diamond is from about 50 W/mK to about 500 W/mK.

25. The apparatus of claim 24, wherein the at least one layer of synthetic diamond has a thickness within a range from about 20 nanometers (nm) to about 2,000 nm.

26. (canceled)

27. The apparatus of claim 24, wherein the wide-bandgap semiconductor material comprises a material selected from the group consisting of GaN, AlN, InGaN, InAlN, AlGaN, InGaAlN, Ga2O3, ScAlN, and derivatives and combinations thereof.

28. (canceled)

29. The apparatus of claim 28, wherein the single interface includes at least a portion of the at least one layer of synthetic diamond in contact with the at least a portion of the wide-bandgap semiconductor material.

30. The apparatus of claim 24, wherein the semiconductor apparatus does not include a nucleation layer or an intermediating intermediate layer over the at least the portion of the layered structure.

31. The apparatus of claim 24, wherein the interface comprises a thermal boundary having a resistance less than about 50 m²K/GW, as measured by time-domain thermal reflectance.

32. (canceled)

33. The apparatus of claim 24, wherein the interface comprises a charge density less than or equal to about 10¹⁷ carriers/cm² at 23° C. as measured by capacitance-voltage testing.

34. (canceled)

35. The apparatus of claim 24, further comprising at least one additional layer of synthetic diamond over the at least one layer of synthetic diamond.

36. The apparatus of claim 35, wherein a thermal conductivity of the at least one additional layer of synthetic diamond is greater than about 1,000 W/mK.

37. The apparatus of claim 35, wherein the at least one additional layer of synthetic diamond has a thickness of about 500 micrometers or less.

38. The apparatus of claim 24, wherein the interface has a roughness of less than about 5 atomic layers, less than about 3 atomic layers, less than about 2 atomic layers, or less than about 1 atomic layer, when viewed by scanning electron or tunneling electron microscopy.

39. A semiconductor-containing structure comprising a structure of a semiconductor material in contact with at least one layer of synthetic diamond at a single interface, wherein a thermal conductivity of the at least one layer of synthetic diamond is within a range from about 50 W/mK to about 500 W/mK.

40. (canceled)

41. The structure of claim 39, wherein the semiconductor material is a wide-bandgap semiconductor material comprising a material selected from the group consisting of GaN, AlN, InGaN, InAlN, AlGaN, InGaAlN, Ga2O3, ScAlN, and derivatives and combinations thereof.

42. The structure of claim 39, wherein the at least one layer of synthetic diamond has a thickness within a range from about 20 nanometers (nm) to about 2,000 nm.

43. (canceled)

44. The structure of claim 39, wherein the structure does not include a nucleation layer or an intermediating intermediate layer over the at least the portion of the layered structure.

45. The structure of claim 39, wherein the single interface comprises a thermal boundary having a resistance less than about 50 m²K/GW, as measured by time-domain thermal reflectance.

46. (canceled)

47. The structure of claim 39, wherein the single interface comprises a charge density less than or equal to about 10¹⁷ carriers/cm² at 23° C. as measured by capacitance-voltage testing.

48. (canceled)

49. The structure of claim 39, further comprising at least one additional layer of synthetic diamond over the at least one layer of synthetic diamond.

50. The structure of claim 49, wherein a thermal conductivity of the at least one additional layer of synthetic diamond is greater than about 1,000 W/mK.

51. The structure of claim 49, wherein the at least one additional layer of synthetic diamond has a thickness of about 500 micrometers or less.

52. The structure of claim 39, wherein the single interface has a roughness of less than about 5 atomic layers, less than about 3 atomic layers, less than about 2 atomic layers, or less than about 1 atomic layer, when viewed by scanning electron or tunneling electron microscopy.

53.-69 (canceled)
